(19) United States
(12) Patent Application Publication
(10) Pub. No.: US 2024/0258290 A1
(43) Pub. Date: Aug. 1, 2024

(54) DISPLAY PANEL AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yudiao CHENG, Beijing (CN); Zhuoran YAN, Beijing (CN); Yao HUANG, Beijing (CN); Qiwei WANG, Beijing (CN); Yue LONG, Beijing (CN); Weiyun HUANG, Beijing (CN)

(21) Appl. No.: 18/006,587

(22) PCT Filed: May 13, 2022
(86) PCT No.: PCT/CN2022/092866

§ 371 Date: Jan. 24, 2023

(30) Foreign Application Priority Data
Jan. 29, 2022 (WO) PCT/CN2022/075077

(51) Int. Cl. H01L 25/16; H01L 25/075; H01L 27/12

(52) U.S. Cl. CPC H01L 25/167; H01L 25/0753; H01L 27/124

(57) ABSTRACT

A display panel has a first region and a second region. The display panel includes: a plurality of first light-emitting devices in the first region; a plurality of second light-emitting devices, a plurality of first pixel circuits, and a plurality of second pixel circuits in the second region; and a plurality of connection lines in the first region and the second region. At least one first pixel circuit is electrically connected to at least one first light-emitting device through at least one connection line, at least one second pixel circuit is electrically connected to at least one second light-emitting device. The at least one row of first light-emitting devices includes light-emitting repeat units arranged in a first direction, and a light-emitting repeat unit includes first light-emitting devices; and connection lines connected to at least two first light-emitting devices in the light-emitting repeat units are made of different materials.

### CROSS-REFERENCE TO RELATED APPLICATIONS

This application is a national phase entry under 35 USC 371 of International Patent Application No. PCT/CN2022/092866, filed on May 13, 2022, which claims priority to PCT Patent Application No. PCT/CN2022/075077, filed on Jan. 29, 2022, which is incorporated herein by reference in its entirety.

### TECHNICAL FIELD

The present disclosure relates to the field of display technologies, and in particular, to a display panel and a display apparatus.

### BACKGROUND

With the continuous development of science and technologies, there is increasing pursuit of users for a screen-to body ratio of a display apparatus (a ratio of an area of a display region of a display screen to an area of a front surface of the display apparatus).

In the related art, a concept of a full screen is proposed. That is, optical component(s) (such as image collector(s)) in the display apparatus are provided under the display screen in the display apparatus to increase the ratio of the area of the display region to the area of the front surface of the display apparatus, so that the ratio approaches 100%.

### SUMMARY

In an aspect, a display panel is provided. The display panel has a first region and a second region, the second region surrounding at least part of the first region. The display panel includes: a plurality of first light-emitting devices located in the first region; a plurality of second light-emitting devices, a plurality of first pixel circuits and a plurality of second pixel circuits that are located in the second region; and a plurality of connection lines located in the first region and the second region. At least one first pixel circuit in the plurality of first pixel circuits is electrically connected to at least one first light-emitting device in the plurality of first light-emitting devices through at least one connection line in the plurality of connection lines, and at least one second pixel circuit in the plurality of second pixel circuits is electrically connected to at least one second light-emitting device in the plurality of second light-emitting devices. At least one row of first light-emitting devices include a plurality of light-emitting repeat units that are arranged in a first direction, and a light-emitting repeat unit includes first light-emitting devices; connection lines connected to at least two first light-emitting devices in the plurality of light-emitting repeat units are made of different materials.

In some embodiments, a direction directed from an alignment center of the plurality of light-emitting repeat units to an end of the plurality of light-emitting repeat units in the first direction is a first set direction; a light-emitting repeat unit adjacent to the second region in the first set direction in the plurality of light-emitting repeat units is referred to as a first repeat unit, and a connection line connected to at least one first light-emitting device in the first repeat unit is a metal connection line.

In some embodiments, a direction directed from the alignment center of the plurality of light-emitting repeat units to another end of the plurality of light-emitting repeat units in the first direction is a second set direction; and the first repeat unit includes a first first light-emitting device to a fourth first light-emitting device that are sequentially arranged in the second set direction. The connection line connected to a second first light-emitting device in the first repeat unit is the metal connection line.

In some embodiments, connection lines connected to the first first light-emitting device, a third first light-emitting device and the fourth first light-emitting device in the first repeat unit are transparent connection lines. The transparent connection lines are arranged in a different layer from the metal connection line.

In some embodiments, connection lines connected to the first first light-emitting device and a third first light-emitting device in the first repeat unit extend to the second region through one of two wiring regions that are adjacent to the first repeat unit, and connection lines connected to the second first light-emitting device and the fourth first light-emitting device in the first repeat unit extend to the second region through another one of the two wiring regions that are adjacent to the first repeat unit. Any one of the wiring regions extends in the first direction.

In some embodiments, a dimension, in the first direction, of a connection line connected to the first first light-emitting device in the first repeat unit is less than a dimension, in the first direction, of a connection line connected to a third first light-emitting device in the first repeat unit; a dimension, in the first direction, of the connection line connected to the second first light-emitting device in the first repeat unit is less than a dimension, in the first direction, of a connection line connected to the fourth first light-emitting device in the first repeat unit; and the dimension, in the first direction, of the connection line connected to the fourth first light-emitting device is less than the dimension, in the first direction, of the connection line connected to the first first light-emitting device.

In some embodiments, a direction directed from an alignment center of the plurality of light-emitting repeat units to another end of the plurality of light-emitting repeat units in the first direction is a second set direction; a light-emitting repeat unit adjacent to the second region in the second set direction in the plurality of light-emitting repeat units is referred to as a second repeat unit, and a connection line connected to at least one first light-emitting device in the second repeat unit is a metal connection line.

In some embodiments, the second repeat unit includes a first first light-emitting device to a fourth first light-emitting device that are sequentially arranged in the second set direction. The connection line connected to the fourth first light-emitting device in the second repeat unit is the metal connection line.

In some embodiments, connection lines connected to the first first light-emitting device, a second first light-emitting device and a third first light-emitting device in the second repeat unit are transparent connection lines; and the transparent connection lines are arranged in a different layer from the metal connection line.

In some embodiments, connection lines connected to the first first light-emitting device and a third first light-emitting device in the second repeat unit extend to the second region through one of two wiring regions that are adjacent to the second repeat unit, and connection lines connected to a second first light-emitting device and the fourth first light-emitting device in the second repeat unit extend to the second region through another one of the two wiring regions that are adjacent to the second repeat unit. Any one of the wiring regions extends in the first direction.

In some embodiments, a dimension, in the first direction, of a connection line connected to a third first light-emitting device in the second repeat unit is less than a dimension, in the first direction, of a connection line connected to the first first light-emitting device in the second repeat unit; a dimension, in the first direction, of the connection line connected to the fourth first light-emitting device in the second repeat unit is less than a dimension, in the first direction, of a connection line connected to a second first light-emitting device in the second repeat unit; and the dimension, in the first direction, of the connection line connected to the second first light-emitting device is less than the dimension, in the first direction, of the connection line connected to the third first light-emitting device.

In some embodiments, the first first light-emitting device corresponds to a red sub-pixel region, the second first light-emitting device corresponds to a green sub-pixel region, the third first light-emitting device corresponds to a blue sub-pixel region, and the fourth first light-emitting device corresponds to another green sub-pixel region.

In some embodiments, a connection line connected to any one first light-emitting device, other than the first light-emitting device connected to the metal connection line, in the plurality of light-emitting repeat units arranged in the first direction is a transparent connection line. The first region includes at least two sub-regions that are sequentially arranged in a set direction, and the set direction is directed from the alignment center of the plurality of light-emitting repeat units to any one end of the plurality of light-emitting repeat units in the first direction. Transparent connection lines connected to first light-emitting devices that are located in different sub-regions are located in different layers.

The first light-emitting device connected to the metal connection line is located in a sub-region, farthest away from the alignment center of the plurality of light-emitting repeat units, in the at least two sub-regions.

In some embodiments, the at least two sub-regions include a first sub-region, a second sub-region, and a third sub-region that are sequentially arranged in the set direction.

For connection lines connected to W first light-emitting devices that are closest to the alignment center of the plurality of light-emitting repeat units in the plurality of light-emitting repeat units, a connection line includes a first wiring segment, a second wiring segment and a third wiring segment that are connected in sequence; the first wiring segment and the third wiring segment extend in the first direction and are located in different wiring regions, and the second wiring segment extends in a second direction. The second direction intersects the first direction. The wiring regions extend in the first direction. W is a positive integer greater than or equal to 1 and less than or equal to 5. The second wiring segment is located in any one of the first sub-region, the second sub-region and the third sub-region.

In some embodiments, a direction directed from an alignment center of the plurality of light-emitting repeat units to an end of the plurality of light-emitting repeat units in the first direction is a first set direction, and a direction directed from the alignment center of the plurality of light-emitting repeat units to another end of the plurality of light-emitting repeat units in the first direction is a second set direction. Any one light-emitting repeat unit in the plurality of light-emitting repeat units includes a first first light-emitting device to a fourth first light-emitting device that are sequentially arranged in the second set direction. Connection lines connected to the first first light-emitting device and a third first light-emitting device in any one light-emitting repeat unit extend to the second region through one of two wiring regions that are adjacent to the light-emitting repeat unit, and connection lines connected to a second first light-emitting device and the fourth first light-emitting device in any one light-emitting repeat unit extend to the second region through another one of the two wiring regions that are adjacent to the light-emitting repeat unit. Any one wiring region extends in the first direction.

In some embodiments, in the first direction, a dimension of a connection line connected to any one of the first first light-emitting device and the third first light-emitting device is greater than a dimension of a connection line connected to any one of the second first light-emitting device and the fourth first light-emitting device.

In some embodiments, all the first light-emitting devices are divided into a plurality of first basic units, and a first basic unit includes 1k row and 2h columns of first light-emitting device. K and h are positive integers greater than or equal to 1.

In some embodiments, the first region includes at least two sub-regions and an edge region located between the at least two sub-regions and the second region in a set direction. The set direction is directed from the alignment center of the plurality of light-emitting repeat units to any one end of the plurality of light-emitting repeat units in the first direction. At least part of the connection lines are metal connection lines. At least connection lines connected to first light-emitting devices that correspond to green sub-pixel regions in the edge region are metal connection lines. The metal connection lines connected to the first light-emitting devices in the edge region and metal connection lines connected to first light-emitting devices in the first region are arranged in different layers.

In some embodiments, the second region includes a first sub-region and a second sub-region, and the first sub-region is adjacent to the first region. Second light-emitting devices in the plurality of second light-emitting devices are arranged in the first sub-region. All the first light-emitting devices and all the second light-emitting devices located in the first sub-region are divided into a plurality of second basic units, and a second basic unit includes 2k rows and 4h columns of light-emitting devices. K and h are positive integers greater than or equal to 1.

In some embodiments, in first pixel circuits in the plurality of first pixel circuits and second pixel circuits in the plurality of second pixel circuits that are arranged in a same row in the first direction, the first pixel circuits are arranged between multiple second pixel circuits in the second pixel circuits at intervals.

In another aspect, a display apparatus is provided. The display apparatus includes the display panel as described in the embodiments described above and an optical component. An orthographic projection of a photosensitive surface of the optical component on the display panel covers at least the first region.

### BRIEF DESCRIPTION OF THE DRAWINGS

In order to describe technical solutions in the present disclosure more clearly, the accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings In addition, the accompanying drawings to be described below may be regarded as schematic diagrams, but are not limitations on actual sizes of products, actual processes of methods, and actual timings of signals involved in the embodiments of the present disclosure.

FIG. 1 is a structural diagram of a display panel, in accordance with some embodiments of the present disclosure;

FIG. 2 is a sectional view of the display panel shown in FIG. 1 taken along the direction A-A′;

FIG. 3 is a circuit diagram of a sub-pixel, in accordance with some embodiments of the present disclosure;

FIG. 4A is a partial structural diagram of a display panel, in accordance with some embodiments of the present disclosure;

FIG. 4B is a partial structural diagram of another display panel, in accordance with some embodiments of the present disclosure;

FIG. 4C is a partial structural diagram of yet another display panel, in accordance with some embodiments of the present disclosure;

FIG. 4D is a partial structural diagram of yet another display panel, in accordance with some embodiments of the present disclosure;

FIG. 4E is a partial structural diagram of yet another display panel, in accordance with some embodiments of the present disclosure;

FIG. 5A is a partial structural diagram of yet another display panel, in accordance with some embodiments of the present disclosure;

FIG. 5B is a partial structural diagram of yet another display panel, in accordance with some embodiments of the present disclosure;

FIG. 6 is a partial structural diagram of yet another display panel, in accordance with some embodiments of the present disclosure;

FIG. 7A is a partial structural diagram of yet another display panel, in accordance with some embodiments of the present disclosure;

FIG. 7B is a partial structural diagram of yet another display panel, in accordance with some embodiments of the present disclosure;

FIG. 7C is a partial structural diagram of yet another display panel, in accordance with some embodiments of the present disclosure;

FIG. 8 is a partial structural diagram of yet another display panel, in accordance with some embodiments of the present disclosure;

FIG. 9 is a partial structural diagram of yet another display panel, in accordance with some embodiments of the present disclosure;

FIG. 10 is a partial structural diagram of yet another display panel, in accordance with some embodiments of the present disclosure;

FIG. 11 is a partial structural diagram of yet another display panel, in accordance with some embodiments of the present disclosure; and

FIG. 12 is a structural diagram of a display apparatus, in accordance with some embodiments of the present disclosure.

### DETAILED DESCRIPTION

Technical solutions in some embodiments of the present disclosure will be described clearly and completely below with reference to the accompanying drawings.

Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure.

Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the terms “a plurality of”, “the plurality of” and “multiple” each mean two or more unless otherwise specified.

In the description of some embodiments, the terms such as “coupled” and “connected” and derivatives thereof may be used. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

In addition, the phase “based on” used is meant to be open and inclusive, since a process, step, calculation or other action that is “based on” one or more of the stated conditions or values may, in practice, be based on additional conditions or values exceeding those stated.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in apparatuses, and are not intended to limit the scope of the exemplary embodiments.

In circuit structures (e.g., a shift register and a pixel circuit) provided in embodiments of the present disclosure, transistors may be thin film transistors (TFTs), metal oxide semiconductor (MOS) transistors, or other switching devices with same properties, and the embodiments of the present disclosure are described by taking the thin film transistors as an example.

In the circuit structures provided in the embodiments of the present disclosure, a control electrode of each transistor used in each circuit is a gate of the transistor, a first electrode of the transistor is one of a source and a drain of the transistor, and a second electrode of the transistor is the other one of the source and the drain of the transistor. Since the source and the drain of the transistor may be symmetrical in structure, the source and the drain of the transistor may be indistinguishable in structure. That is, the first electrode and the second electrode of the transistor in the embodiments of the present disclosure may be indistinguishable in structure. For example, in a case where the transistor is a P-type transistor, the first electrode of the transistor is the source, and the second electrode of the transistor is the drain. As another example, in a case where the transistor is an N-type transistor, the first electrode of the transistor is the drain, and the second electrode of the transistor is the source. A film layer in which the source and the drain are located may be referred to as a source-drain electrode layer.

In the embodiments of the present disclosure, a capacitor may be a capacitor device that is fabricated separately through processes. For example, special capacitor electrodes are fabricated to form the capacitor device. Each capacitor electrode of the capacitor may be fabricated through a metal layer, a semiconductor layer (e.g., doped polysilicon), or the like. The capacitor may also be a parasitic capacitor formed by transistors, or by a transistor itself and another device or line, or by lines of a circuit itself.

In the circuit provided in embodiments of the present disclosure, “nodes” do not represent actual components, but represent junctions of relevant electrical connections in a circuit diagram. That is, these nodes are nodes equivalent to junctions of relevant electrical connections in the circuit diagram.

Transistors included in the circuit provided in the embodiments of the present disclosure may all be N-type transistors or P-type transistors. Alternatively, a part of the transistors included in the circuit may be N-type transistors, and another part of the transistors may be P-type transistors.

In the embodiments of the present disclosure, an “effective level” refers to a level that can enable a transistor to be turned on. The P-type transistor may be turned on under control of a low-level signal, and the N-type transistor may be turned on under control of a high-level signal.

Hereinafter, the description is made by taking an example where the transistors in the circuit provided in the embodiments of the present disclosure are all P-type transistors (in this case, the effective level is a low level). It will be noted that, transistors in each circuit mentioned below are of a same conduction type, which may simplify process flow, reduce process difficulty, and improve a yield of products (e.g., a display panel and a display apparatus).

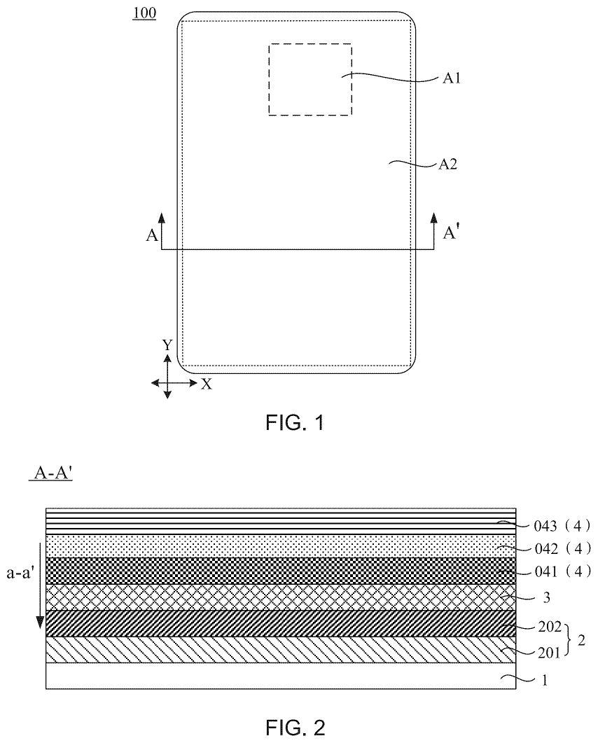

Referring to FIG. 1, some embodiments of the present disclosure provide a display panel 100. The display panel 100 has a first region A1 and a second region A2.

The second region A2 surrounds at least part of the first region A1.

There may be at least one first region A1, and there may be, for example, one second region A2. As shown in FIG. 1, a structure of the display panel 100 will be schematically described by taking an example where there is one first region A1 and one second region A2.

In some examples, as shown in FIG. 1, the second region A2 may completely surround the first region A1. In this case, the first region A1 may be in a shape of, for example, a circle, an ellipse, a rectangle, or other irregular pattern.

In some other examples, the second region A2 may surround part of the first region A1. That is, a portion of a border of the second region A2 is in contact with a portion of a border of the first region A1. In this case, the first region A1 may be in a shape of, for example, the rectangle, a rounded rectangle, a water droplet or a semicircle.

In some embodiments, referring to FIG. 2, the display panel 100 may include a substrate 1.

A type of the substrate 1 may vary, and may be set according to actual needs.

In some examples, the substrate 1 may be a rigid substrate. The rigid substrate may be a glass substrate or a polymethyl methacrylate (PMMA) substrate.

In some examples, the substrate 1 may be a flexible substrate. The flexible substrate may be a polyethylene terephthalate (PET) substrate, a polyethylene naphthalate two formic acid glycol ester (PEN) substrate or a polyimide (PI) substrate. In this case, the display panel 100 may, for example, achieve flexible display.

In some embodiments, with continued reference to FIG. 2, the display panel 100 may further include a pixel circuit layer 2 disposed on the substrate 1.

For example, the pixel circuit layer 2 may include a plurality of first pixel circuits 21 and a plurality of second pixel circuits 22.

Structures of the first pixel circuit 21 and the second pixel circuit 22 each may vary, and may be set according to actual needs. For example, the first pixel circuit 21 or the second pixel circuit 22 may be of a structure with “2T1C”, “6T1C”, “7T1C”, “6T2C” or “7T2C”. “T” represents a transistor, and the number before “T” represents the number of transistors. “C” represents a storage capacitor, and the number before “C” represents the number of storage capacitor(s).

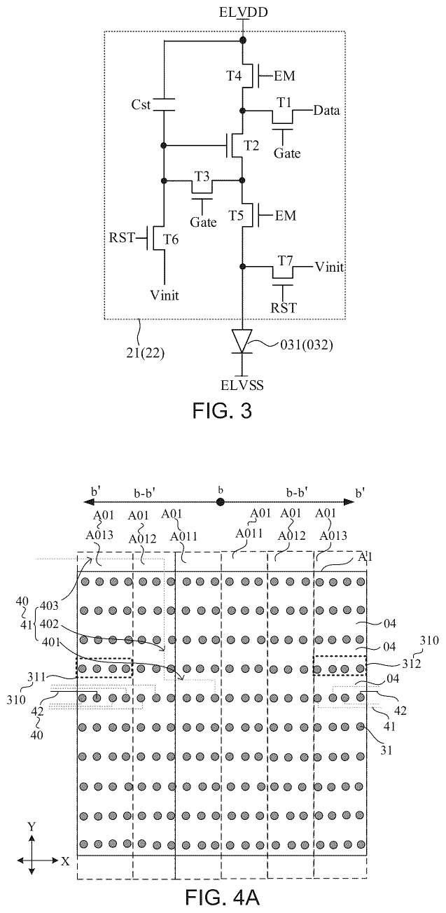

In some example, as shown in FIG. 3, a structure of the first pixel circuit 21 and a structure of the second pixel circuit 22 may be the same. For example, the first pixel circuit 21 and the second pixel circuit 22 are both of the structure with “7T1C”. FIG. 3 is an equivalent circuit diagram of the second pixel circuit 22. Of course, an equivalent circuit of the first pixel circuit 21 may be the same as the equivalent circuit shown in FIG. 3.

For example, the second pixel circuit 22 includes: a switching transistor T1, a driving transistor T2, a compensation transistor T3, a first light-emitting control transistor T4, a second light-emitting control transistor T5, a first reset transistor T6, a second reset transistor T7 and a storage capacitor Cst.

In a case where a reset signal transmitted by a reset signal terminal RST is at the effective level, the first reset transistor T6 and the second reset transistor T7 may be turned on under control of the reset signal, so as to receive an initial signal transmitted from an initial signal terminal Vinit. The first reset transistor T6 may transmit the initial signal to an end of the storage capacitor Cst to reset it. The second reset transistor T7 may transmit the initial signal to a second electrode thereof to reset it. The driving transistor T2 may be turned on under control of the initial signal.

In a case where a scan signal transmitted by a scan signal terminal Gate is at the effective level, the switch transistor T1 and the compensation transistor T3 may be turned on under control of the scan signal, a data signal transmitted by a data signal terminal Data may be transmitted to a control electrode of the driving transistor T2 through the switch transistor T1, the driving transistor T2 and the compensation transistor T3 in sequence, so that the control electrode of the driving transistor T2 is charged until the driving transistor T2 is turned off. In this case, compensation for a threshold voltage of the driving transistor T2 is completed.

In a case where an enable signal transmitted by an enable signal terminal EM is at the effective level, the first light-emitting control transistor T4 and the second light-emitting control transistor T5 may be turned on under control of the enable signal, so that a first voltage signal from a first voltage signal terminal ELVDD is received by the driving transistor T2. The driving transistor T2 may generate a driving signal according to the data signal and the first voltage signal. The driving signal may be transmitted to the second electrode of the second reset transistor T7.

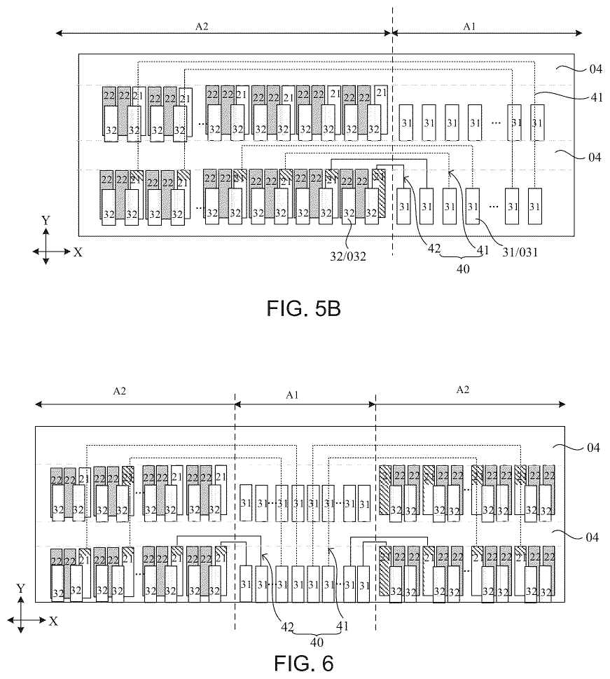

In some embodiments, referring to FIGS. 5A, 5B and 6, the plurality of second pixel circuits 22 may be arranged in a plurality of columns in a first direction X, and arranged in a plurality of rows in a second direction Y. Each column of second pixel circuits 22 may include second pixel circuits 22 that are arranged along the second direction Y in sequence. Each row of the second pixel circuits 22 may include second pixel circuits 22 that are arranged along the first direction X in sequence. It will be noted that the row and the column are relative concepts. For example, as for FIGS. 1, 5A, 5B and 6, the first direction X may be a row direction, and the second direction Y may be a column direction. Alternatively, the first direction X may be the column direction, and the second direction Y may be the row direction.

The first direction X intersects the second direction Y. An included angle between the first direction X and the second direction Y may be set according to actual needs. For example, the included angle between the first direction X and the second direction Y is 85°, 88° or 90°.

In some embodiments, first pixel circuits 21 in a column are distributed between the second pixel circuits 22 in a column of second pixel circuits 22 at intervals.

The number of rows of second pixel circuits 22 disposed between any two adjacent rows of first pixel circuits 21 may be the same, thereby ensuring uniformity of the arrangement.

In some other embodiments, with continued reference to FIGS. 5A, 5B and 6, first pixel circuits 21 in a row are distributed between the second pixel circuits 22 in a row of second pixel circuits 22 at intervals.

For example, there is one column of first pixel circuits 21 between every two groups each consisting of adjacent multiple columns of second pixel circuits 22. That is, every two adjacent columns of first pixel circuits 21 may be spaced by the adjacent multiple columns of second pixel circuits 22.

The number of columns of second pixel circuits 22 disposed between any two adjacent columns of first pixel circuits 21 may be the same, thereby ensuring uniformity of the arrangement.

It will be noted that, the number of the columns of second pixel circuits 22 between any two adjacent columns of first pixel circuits 21 may be two, three or more, and is not limited in the embodiments of the present disclosure.

For example, as shown in FIGS. 5A, 5B and 6, two columns of second pixel circuits 22 are disposed between any two adjacent columns of first pixel circuits 21.

In some embodiments, the pixel circuit layer 2 included in the display panel 100 may include a semiconductor layer, a first gate conductive layer, a second gate conductive layer and a source-drain electrode layer that are sequentially stacked in a direction perpendicular to the substrate 1 (i.e., a thickness direction of the substrate 1) and away from the substrate 1.

In some examples, the semiconductor layer may include an active layer of each transistor in the first pixel circuits 21 and the second pixel circuits 22. The first gate conductive layer may include a control electrode of each transistor in the first pixel circuits 21 and the second pixel circuits 22, and an electrode plate of each storage capacitor in the first pixel circuits 21 and the second pixel circuits 22. Of course, the first gate conductive layer may further include gate lines for transmitting scan signals, and reset signal lines for transmitting reset signals. The second gate conductive layer may include another electrode plate of each storage capacitor in the first pixel circuits 21 and the second pixel circuits 22. Of course, the second gate conductive layer may further include initial signal lines for transmitting initial signals. The source-drain electrode layer may include a first electrode and a second electrode of each transistor in the first pixel circuits 21 and the second pixel circuits 22. In a case where at least one of transistors included in the first pixel circuit 21 includes a first source and a first drain, and at least one of transistors included in the second pixel circuit 22 includes a second source and a second drain, a layer in which the first source and the first drain are located may be referred to as a first source-drain electrode layer, and a layer in which the second source and the second drain are located may be referred to as a second source-drain electrode layer. As shown in FIG. 2, the first source-drain electrode layer 201 and the second source-drain electrode layer 202 are illustrated, and the first source-drain electrode layer 201 and the second source-drain electrode layer 202 are away from the substrate 1 in sequence.

In some embodiments, with continued reference to FIG. 2, the display panel 100 may further include a light-emitting device layer 3 located on a side of the pixel circuit layer 2 away from the substrate 1.

In some examples, the light-emitting device layer 3 may include a plurality of light-emitting devices.

For example, referring to FIG. 5B, the plurality of light-emitting devices include a plurality of first light-emitting devices 031 and a plurality of second light-emitting devices 032.

A structure of the first light-emitting device 031 and a structure of the second light-emitting device 032 may be, for example, the same.

In some examples, the first light-emitting device 031 and the second light-emitting device 032 each include an anode, a light-emitting functional layer and a cathode.

In some examples, a first pixel circuit 21 may be electrically connected to a first light-emitting device 031. For example, the first pixel circuits 21 and the first light-emitting devices 031 are arranged in one-to-one correspondence. The first pixel circuit 21 may provide a driving signal for the corresponding first light-emitting device 031. In some other examples, a first light-emitting device 031 may be coupled to multiple first pixel circuits 21; or multiple first light-emitting devices 031 may be coupled to a first pixel circuit 21.

In some examples, a second pixel circuit 22 may be electrically connected to a second light-emitting device 032. For example, the second pixel circuits 22 and the second light-emitting devices 032 are arranged in one-to-one correspondence. The second pixel circuit 22 may provide a driving signal for the corresponding second light-emitting device 032. In some other examples, a second light-emitting device 032 may be coupled to multiple second pixel circuits 22; or multiple second light-emitting devices 032 may be coupled to a second pixel circuit 22.

In some examples, with continued reference to FIGS. 5A, 5B and 6, the plurality of first pixel circuits 21 and the plurality of second pixel circuits 22 of the pixel circuit layer 2 may all be located in the second region A2; the plurality of first light-emitting devices 031 of the light-emitting device layer 3 are all located in the first region A1, and the second light-emitting devices 032 of the light-emitting device layer 3 are all located in the second region A2. That is, only the plurality of first light-emitting devices 031 are arranged in the first region A1, and respective first pixel circuits 21 are not arranged therein; the second light-emitting devices 032, the second pixel circuits 22 corresponding to the second light-emitting devices 032, and the first pixel circuits 21 corresponding to the plurality of first light-emitting devices 031 are arranged in the second region A2. That is, no pixel circuit is provided in the first region A1.

In some examples, as shown in FIGS. 5A and 6, the first pixel circuits 21 are disposed on two sides of the first region A1.

In some examples, as shown in FIG. 5B, the first pixel circuits 21 are disposed on one side of the first region A1.

It will be noted that, in order to provide sufficient space for the arrangement of the first pixel circuits 21 without reducing the number of the second light-emitting devices 032 in the second region A2, the second pixel circuits 22 in the second region A2 may be compressed along the first direction X, so as to place the first pixel circuits 21 corresponding to the first light-emitting devices 031 in the second region A2.

In the examples of the present disclosure, the first pixel circuits 21 that provide driving signals for the respective first light-emitting devices 031 are arranged in the second region A2, which reduces blocking of light by structures in the first region A1, so that external light can pass through a gap between any two adjacent first light-emitting devices 031 from a side (e.g., a light exit side) of a portion of the display panel 100 in the first region A1, and then exit from another side (e.g., a non-light exit side) of the portion of the display panel 100 in the first region A1. As a result, the portion of the display panel 100 in the first region A1 has a relatively high light transmittance.

In some examples, a distribution density of the first light-emitting devices 031 may be the same as a distribution density of the second light-emitting devices 032. Thus, it may reduce brightness and resolution differences between the first region A1 and the second region A2, thereby achieving a more uniform display effect of a full screen; and it may also help ensure that the display panel 100 has a relatively good image display quality.

In some examples, the distribution density of the first light-emitting devices 031 may be less than the distribution density of the second light-emitting devices 032. Thus, it may reduce blocking of the first light-emitting devices 031 to the external light by increasing a spacing between any two adjacent first light-emitting devices 031, and increase an area of a light-transmissive portion of the display panel 100 in the first region A1. Therefore, it may further increase an amount of external light that is able to pass through the portion of the display panel 100 in the first region A1, so that the portion of the display panel 100 in the first region A1 has a relatively high light transmittance.

In some embodiments, with continued reference to FIG. 2, the display panel 100 may further include at least two transparent conductive layers 4 located on a side of the light-emitting device layer 3 away from the substrate 1. The at least two transparent conductive layers 4 may be sequentially stacked in the direction perpendicular to the substrate 1. For example, the number of the transparent conductive layers 4 may be two or three.

For example, as shown in FIG. 2, the number of the transparent conductive layers 4 is three. A first transparent conductive layer 041, a second transparent conductive layer 042 and a third transparent conductive layer 043 are all located on the side of the light-emitting device layer 3 away from the substrate 1, and the first transparent conductive layer 041, the second transparent conductive layer 042 and the third transparent conductive layer 043 are away from the substrate 1 in sequence.

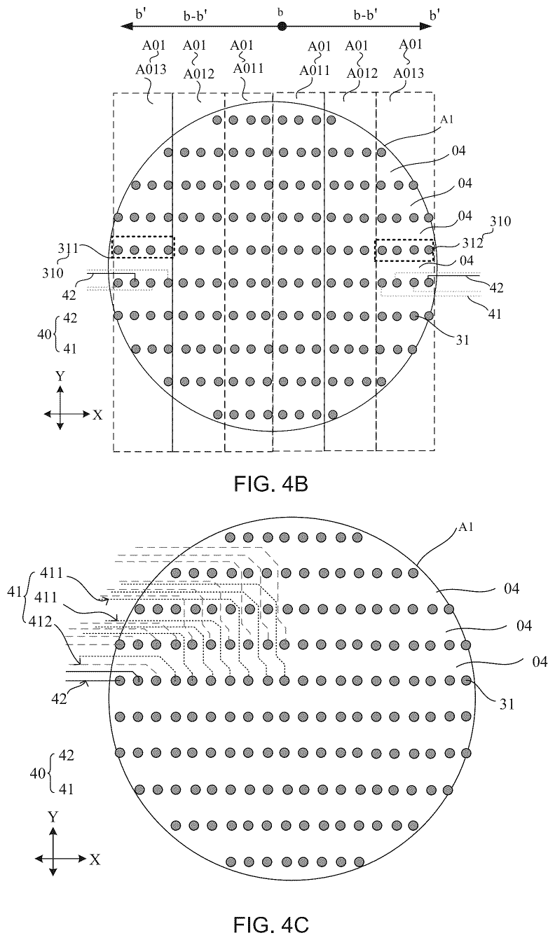

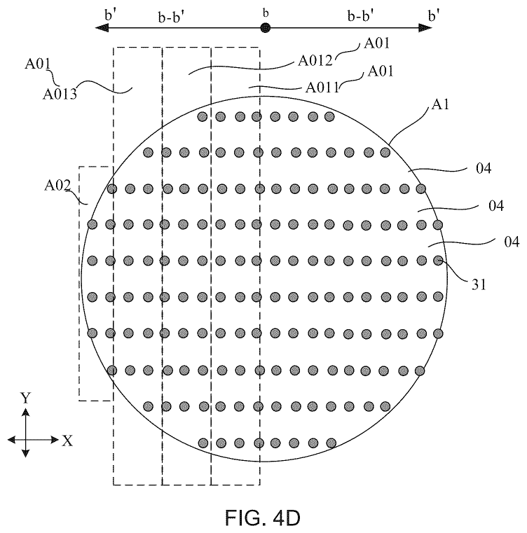

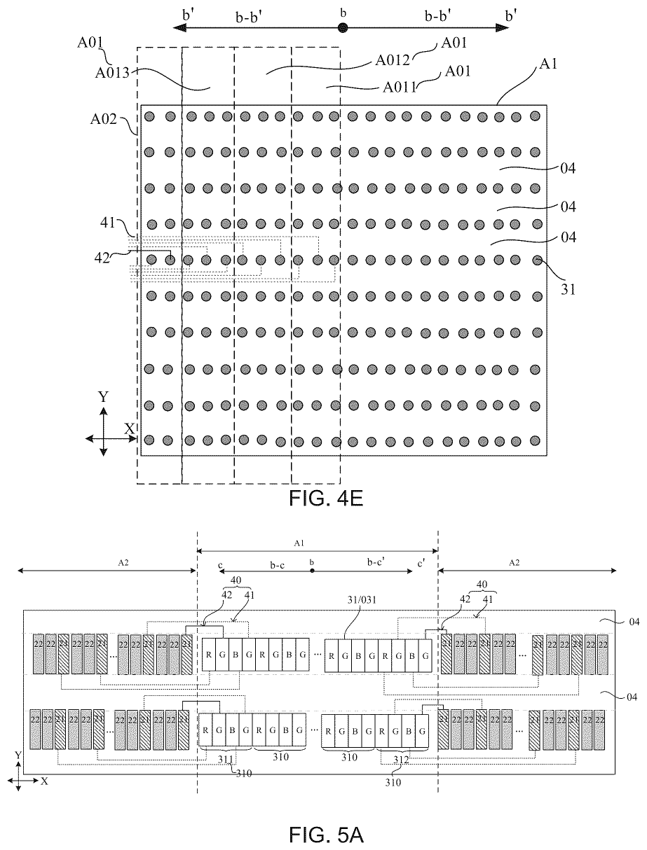

In some embodiments, referring to FIGS. 4A to 6, a wiring region 04 is adjacent to a row of first driving electrodes 31. The display panel 100 further includes a plurality of connection lines 40. A connection line 40 extends to the second region A2 through a wiring region 04. An end of the connection line 40 is electrically connected to a first light-emitting device 031 in a row of first light-emitting devices 031, and the other end of the connection line 40 is electrically connected to the first pixel circuit 21 that is located in the second region A2 and corresponds to the first light-emitting device 031. Thus, an electrical connection between the first pixel circuit 21 and the corresponding first light-emitting device 031 may be achieved by using the connection line 40, so that the first pixel circuit 21 may transmit the driving signal to the corresponding first light-emitting device 031 through the connection line 40.

In some examples, the first pixel circuit 21 may be connected to the anode of the corresponding first light-emitting device 031 through the connection line 40. Some embodiments are described below by taking an example where the anode of the first light-emitting device is connected to the connection line.

In some examples, the anode of the first light-emitting device 031 is the first driving electrode 31, and the anode of the second light-emitting device 032 is a second driving electrode 32.

In some examples, at least one first pixel circuit 21 in the plurality of first pixel circuits 21 is electrically connected to at least one first driving electrode 31 in a plurality of first driving electrodes 31 through at least one connection line 40 in the plurality of connection lines 40.

In some examples, at least one second pixel circuit 22 in the plurality of second pixel circuits 22 is electrically connected to at least one second driving electrode 32 in a plurality of second driving electrodes 32.

In some embodiments, as shown in FIGS. 4A to 6, connection lines 40 connected to at least one row of first driving electrodes 31 extend to the second region A2 through at least one wiring region 04.

The connection lines 40 connected to the at least one row of first driving electrodes 31 extend to the second region A2 through the at least one wiring region 04, and are electrically connected to respective first pixel circuits 21 that are located in the second region A2, so that driving signals may be transmitted from the first pixel circuits 21 to the corresponding first driving electrodes 31 through the connection lines 40.

It will be noted that, the description that “the connection lines 40 connected to the at least one row of first driving electrodes 31 extend to the second region A2 through the at least one wiring region 04” may mean that, the connection lines 40 connected to the at least one row of first driving electrodes 31 extend to the second region A2 through one wiring region 04; or the connection lines 40 connected to the at least one row of first driving electrodes 31 extend to the second region A2 through two or more wiring regions 04. The embodiments of the present disclosure are not limited to this. For example, as shown in FIGS. 4A, 4B, 4E, 5A, 5B and 6, the connection lines 40 connected to the at least one row of first driving electrodes 31 extend to the second region A2 through two wiring regions 04; or as shown in FIG. 4C, the connection lines 40 connected to the at least one row of first driving electrodes 31 extend to the second region A2 through three wiring regions 04.

In some examples, referring to FIGS. 4A and 5A, the at least one row of first light-emitting devices 031 includes a plurality of light-emitting repeat units 310 that are arranged in the first direction. A light-emitting repeat unit 310 includes multiple first light-emitting devices 031.

In some examples, the first direction is the row direction; in some other examples, the first direction is the column direction, and the embodiments of the present disclosure are not limited thereto. For example, as shown in FIGS. 4A and 5A, the at least one row of the first driving electrodes 31 includes the plurality of light-emitting repeat units 310 that are arranged in the row direction.

In some examples, referring to FIGS. 4A and 5A, connection lines connected to at least two first driving electrodes 31 in the plurality of light-emitting repeat units 310 are made of different materials.

For example, a connection line connected to at least one first driving electrode 31 in the plurality of light-emitting repeat units 310 is made of a transparent material, and a connection line connected to at least one other first driving electrode 31 in the plurality of light-emitting repeat units 310 is made of an opaque material (e.g., a metallic material).

Thus, in the display panel 100 provided in the embodiments of the present disclosure, the connection lines that are respectively connected to the at least two first driving electrodes 31 in the plurality of light-emitting repeat units 310 are made of different materials, which may increase an arrangement space for connection lines 40 that are electrically connected to a row of first driving electrodes 31, thereby achieving arrangement of a large number of connection lines 40 in a limited space.

In some embodiments, referring to FIG. 5A, a direction directed from an alignment center b of the plurality of light-emitting repeat units 310 to an end c of the plurality of light-emitting repeat units 310 in the first direction is referred to as a first set direction b-C.

In some examples, a light-emitting repeat unit 310, adjacent to the second region A2 in the first set direction b-c, in the plurality of light-emitting repeat units 310 is referred to as a first repeat unit 311. A connection line connected to at least one first driving electrode 31 in the first repeat unit 311 is a metal connection line 42.

It will be noted that “the light-emitting repeat unit 310, adjacent to the second region A2 in the first set direction b-c, in the plurality of light-emitting repeat units 310” refers to a light-emitting repeat unit 310 in the plurality of light-emitting repeat units 310 that is closest to the second region A2 in the first set direction b-c. That is, no light-emitting repeat unit 310 exists between the second region A2 and the first repeat unit 311.

In the embodiments, the first driving electrode 31 connected to the metal connection line 42 is arranged in the first repeat unit 311. Since the first repeat unit 311 in the plurality of light-emitting repeat units 310 is closest to the second region A2, the metal connection line 42 may be avoided from passing through a central region of the first region A1, thereby avoiding affecting a transmittance of the central region of the first region A1.

In some embodiments, referring to FIG. 5A, a direction directed from the alignment center b of the plurality of light-emitting repeat units 310 to the other end c′ of the plurality of light-emitting repeat units 310 in the first direction is referred to as a second set direction b-c′.

In some examples, a light-emitting repeat unit 310, adjacent to the second region A2 in the second set direction b-c′, in the plurality of light-emitting repeat units 310 is referred to as a second repeat unit 312. A connection line connected to at least one first driving electrode 31 in the second repeat unit 312 is a metal connection line 42.

It will be noted that “the light-emitting repeat unit 310, adjacent to the second region A2 in the second set direction b-c′, in the plurality of light-emitting repeat units 310” refers to a light-emitting repeat unit 310 in the plurality of light-emitting repeat units 310 that is closest to the second region A2 in the second set direction b-c′. That is, no light-emitting repeat unit 310 exists between the second region A2 and the second repeat unit 312.

In the embodiments, the first driving electrode 31 connected to the metal connection line 42 is arranged in the second repeat unit 312. Since the second repeat unit 312 in the plurality of light-emitting repeat units 310 is closest to the second region A2, the metal connection line 42 may be avoided from passing through the central region of the first region A1, thereby avoiding affecting the transmittance of the central region of the first region A1.

In some examples, the connection lines 40 connected to the at least one row of first driving electrodes 31 are located in different layers.

It can be understood by those skilled in the art that, the description that “the connection lines 40 connected to the at least one row of first driving electrodes 31 are located in different layers” means that the connection lines 40 connected to the at least one row of first driving electrodes 31 are located in different layers in a thickness direction of the display panel 100 (e.g., in a direction a-a′ shown in FIG. 2). For example, connection lines 40 connected to a row of first driving electrodes 31 are located in at least one source-drain electrode layer and at least one transparent conductive layer. As another example, the connection lines 40 connected to the row of first driving electrodes 31 are located in at least two transparent conductive layers.

Thus, for the display panel 100 provided in the embodiments of the present disclosure, by arranging the connection lines 40 connected to the at least one row of first driving electrodes 31 to be in different layers, it may be possible to increase the arrangement space for the connection lines 40 that are electrically connected to the row of first driving electrodes 31. As a result, it achieves the arrangement of the large number of connection lines 40 in the limited space; and it avoids a problem that some of the first driving electrodes 31 fail to be electrically connected to respective first pixel circuits 21 through connection lines 40 due to arrangement of a lot of connection lines 40 in a same layer in a case where the number of first driving electrodes 31 in the row of first driving electrodes 31 are large.

It will be noted that, referring to FIG. 5A, the first region A1 may include a plurality of green sub-pixel regions G, a plurality of blue sub-pixel regions B and a plurality of red sub-pixel regions R. The plurality of first driving electrodes 31 include first driving electrodes 31 corresponding to the red sub-pixel regions R, first driving electrodes 31 corresponding to the blue sub-pixel regions B and first driving electrodes 31 corresponding to the green sub-pixel regions G.

In some embodiments, with continued reference to FIG. 5A, a connection line connected to a first driving electrode 31, which corresponds to at least one green sub-pixel region G, in the first repeat unit 311 is a metal connection line 42.

It will be noted that, connection lines connected to first driving electrodes 31 in the first repeat unit 311 that respectively correspond to a red sub-pixel region R and a blue sub-pixel region B may be metal connection lines 42 or not, and the embodiments of the present disclosure are not limited thereto.

In some examples, with continued reference to FIG. 5A, a connection line connected a first driving electrode 31, which corresponds to at least one green sub-pixel region G, in the second repeat unit 312 is a metal connection line 42.

Connection lines connected to first driving electrodes 31 in the second repeat unit 312 that respectively correspond to a red sub-pixel region R and a blue sub-pixel region B may be metal connection lines 42 or not, and the embodiments of the present disclosure are not limited thereto.

It can be understood by those skilled in the art that, compared with the red sub-pixel and the blue sub-pixel, the green sub-pixel needs a different charging time from the red sub-pixel and the blue sub-pixel when they need to be lit.

In the embodiments, by making the connection line connected to the green sub-pixel to be the metal connection lines 42, it may be possible to reduce a parasitic capacitance of the connection line connected to the green sub-pixel. In a same time, the charging time of the green sub-pixel is long, and thus the green sub-pixel has a full amount of charge, and is easy to be lit. As a result, the display effect of the display panel is improved.

In some embodiments, referring to FIG. 5A, the first repeat unit 311 includes a first first driving electrode to a fourth first driving electrode that are sequentially arranged in the second set direction b-c′.

In an example, with continued reference to FIG. 5A, a connection line connected to a second first driving electrode 31 in the first repeat unit 311 is a metal connection line 42.

In some examples, a first driving electrode 31 is connected to a connection line through a connection block.

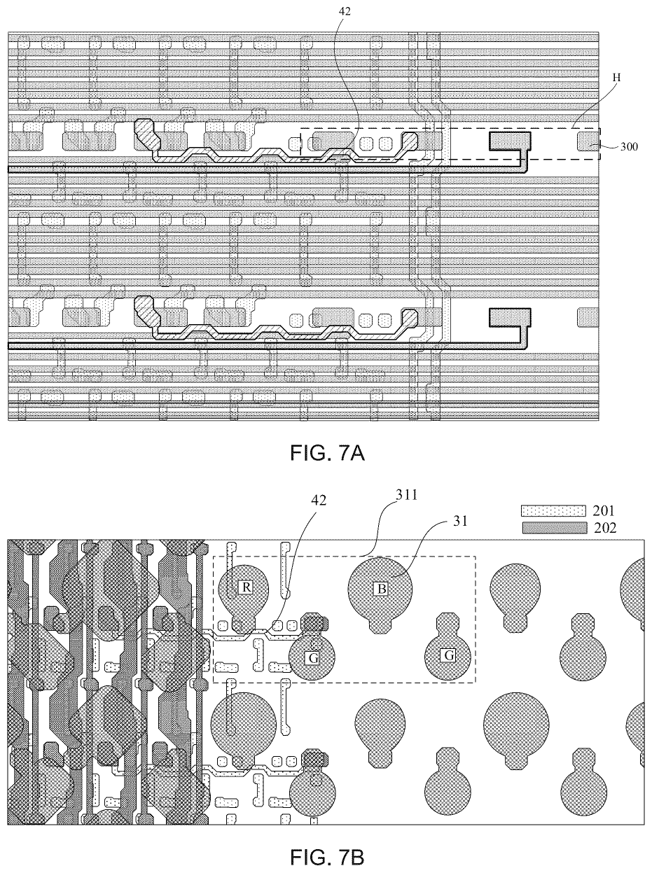

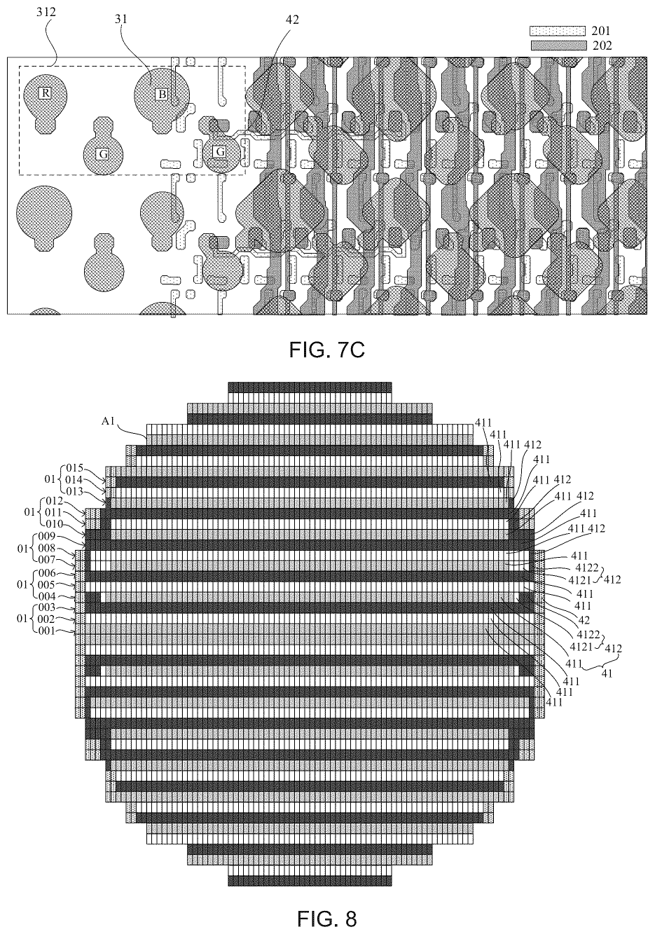

For example, referring to FIG. 7A, four connection blocks 300 in the dashed box are used for connecting four light-emitting devices in a light-emitting repeat unit, respectively. In FIG. 7A, only four connection blocks 300 in a region H where the first repeat unit 311 is located are illustrated, and a connection block 300 corresponding to the second first driving electrode 31 in the first repeat unit 311 is connected to the metal connection line 42.

Referring to FIGS. 7A and 7B, a shape of the metal connection line 42 connected to the second first driving electrode 31 in the first repeat unit 311 is wavy, which enables the metal connection line 42 to avoid other wirings provided in a same layer as the metal connection line 42, thereby preventing a short circuit between the metal connection line 42 and the other wirings.

In some embodiments, referring to FIG. 5A, the second repeat unit 312 includes a first first driving electrode to a fourth first driving electrode that are sequentially arranged in the second set direction b-c′.

In some examples, with continued reference to FIG. 5A, a connection line connected to the fourth first driving electrode 31 in the second repeat unit 312 is a metal connection line 42.

In some examples, referring to FIG. 7C, a shape of the metal connection line 42 connected to the fourth first driving electrode 31 in the second repeat unit 312 is wavy, which enables the metal connection line 42 to avoid other wirings provided in a same layer as the metal connection line 42, thereby preventing a short circuit between the metal connection line 42 and the other wirings.

In some examples, referring to FIG. 7B, the metal connection line 42 connected to the second first driving electrode 31 in the first repeat unit 311 may be located in the first source-drain electrode layer 201 or the second source-drain electrode layer 202; and the metal connection line 42 connected to the fourth first driving electrode 31 in the second repeat unit 312 may be located in the first source-drain electrode layer 201 or the second source-drain electrode layer 202.

The metal connection line 42 connected to the second first driving electrode 31 in the first repeat unit 311 and the metal connection line 42 connected to the fourth first driving electrode 31 in the second repeat unit 312 may be disposed in a same layer or in different layers, and the embodiments of the present disclosure are not limited thereto.

For example, as shown in FIGS. 7B and 7C, the metal connection line 42 connected to the second first driving electrode 31 in the first repeat unit 311 and the metal connection line 42 connected to the fourth first driving electrode 31 in the second repeat unit 312 are both located in the first source-drain electrode layer 201.

In some examples, referring to FIGS. 7B and 7C, in a row of first driving electrodes 31, first driving electrodes 31 may be arranged in a staggered manner.

In some embodiments, with continued reference to FIG. 5A, connection lines that are respectively connected to the first first driving electrode 31, the third first driving electrode 31 and the fourth first driving electrode 31 in the first repeat unit 311 are transparent connection lines 41.

In some examples, the metal connection line 42 connected to the second first driving electrode 31 in the first repeat unit 311 is arranged in a different layer from the transparent connection lines 41.

It can be understood by those skilled in the art that, the description that “the metal connection line 42 is arranged in the different layer from the transparent connection lines 41” means that the metal connection line 42 and the transparent connection lines 41 are located in the different layers in the thickness direction of the display panel 100 (e.g., the direction a-a′ shown in FIG. 2).

For example, the metal connection line 42 is located in the first source-drain electrode layer 201 or the second source-drain electrode layer 202, and the transparent connection lines 41 are located in transparent conductive layer(s) 4.

In some examples, with continued reference to FIG. 5A, connection lines that are respectively connected to the first first driving electrode 31, the second first driving electrode 31 and the third first driving electrode 31 in the second repeat unit 312 are transparent connection lines 41.

In some examples, the metal connection line 42 connected to the fourth first driving electrode 31 in the second repeat unit 312 is arranged in a different layer from the transparent connection lines 41.

In some examples, the transparent connection line 41 may be made of a transparent material such as indium tin oxide (ITO) or indium gallium zinc oxide (IGZO).

In the embodiments, by arranging the metal connection line 42 and the transparent connection lines 41 connected to the first driving electrodes 31 in each of the first repeat unit 311 and the second repeat unit 312 to be in different layers, it is possible to increase the arrangement space for connection lines 40 that are electrically connected to first driving electrodes 31. As a result, it achieves the arrangement of the large number of connection lines 40 in the limited space; and it avoids the problem that some of the first driving electrodes 31 fail to be electrically connected to respective first pixel circuits 21 through connection lines 40 due to arrangement of a lot of connection lines 40 in the same layer in a case where the number of first driving electrodes 31 in the row of first driving electrodes 31 are large.

In some embodiments, with continued reference to FIG. 5A, connection lines 40 that are respectively connected to the first first driving electrode 31 and the third first driving electrode 31 in the first repeat unit 311 extend to the second region A2 through one of two wiring regions 04 that are adjacent to a row of first driving electrodes 31 in which the first first driving electrode 31 and the third first driving electrode 31 are located, and connection lines 40 that are respectively connected to the second first driving electrode 31 and the fourth first driving electrode 31 in the first repeat unit 311 extend to the second region A2 through the other one of the two wiring regions 04 that are adjacent to the row of first driving electrodes 31.

In some examples, with continued reference to FIG. 5A, connection lines 40 that are respectively connected the first first driving electrode 31 and the third first driving electrode 31 in the second repeat unit 312 extend to the second region A2 through one of two wiring regions 04 that are adjacent to a row of first driving electrodes 31 in which the first first driving electrode 31 and the third first driving electrode 31 are located, and connection lines 40 that are respectively connected to the second first driving electrode 31 and the fourth first driving electrode 31 in the second repeat unit 312 extend to the second region A2 through the other one of the two wiring regions 04 that are adjacent to the row of first driving electrodes 31.

It will be noted that, the wiring region 04 in which the connection lines 40 that are respectively connected to the first first driving electrode 31 and the third first driving electrode 31 in the first repeat unit 311 are located may be the same as or different from the wiring region 04 in which the connection lines 40 that are respectively connected to the first first driving electrode 31 and the third first driving electrode 31 in the second repeat unit 312 are located; and the wiring region 04 in which the connection lines 40 that are respectively connected to the second first driving electrode 31 and the fourth first driving electrode 31 in the first repeat unit 311 are located may be the same as or different from the wiring region 04 in which the connection lines 40 that are respectively connected to the second first driving electrode 31 and the fourth first driving electrode 31 in the second repeat unit 312 are located. The embodiments of the present disclosure are not limited to this.

For example, as shown in FIG. 5A, the wiring region 04 in which the connection lines 40 that are respectively connected to the first first driving electrode 31 and the third first driving electrode 31 in the first repeat unit 311 are located is the same as the wiring region 04 in which the connection lines 40 that are respectively connected to the first first driving electrode 31 and the third first driving electrode 31 in the second repeat unit 312 are located; and the wiring region 04 in which the connection lines 40 that are respectively connected to the second first driving electrode 31 and the fourth first driving electrode 31 in the first repeat unit 311 are located is the same as the wiring region 04 in which the connection lines 40 that are respectively connected to the second first driving electrode 31 and the fourth first driving electrode 31 in the second repeat unit 312 are located.

By adopting the above arrangement, it is easy to control the wiring arrangement of the connection lines connected to the first first driving electrode 31 and the third first driving electrode 31, and the connection lines connected to the second first driving electrode 31 and the fourth first driving electrode 31.

In some embodiments, with continued reference to FIG. 5A, in the row direction, a dimension of the connection line connected to the first first driving electrode 31 in the first repeat unit 311 is less than a dimension of the connection line connected to the third first driving electrode 31 in the first repeat unit 311.

In some examples, with continued reference to FIG. 5A, in the row direction, a dimension of the connection line connected to the second first driving electrode 31 in the first repeat unit 311 is less than a dimension of the connection line connected to the fourth first driving electrode 31 in the first repeat unit 311.

In some examples, with continued reference to FIG. 5A, in the row direction, the dimension of the connection line connected to the fourth first driving electrode 31 in the first repeat unit 311 is less than the dimension of the connection line connected to the first first driving electrode 31 in the first repeat unit 311.

It will be noted that, by adopting the above arrangement, it may be possible to make first pixel circuits 21 that are respectively connected to the second first driving electrode 31 and the fourth first driving electrode 31 in the first repeat unit 311 be closer to the first region A1 than first pixel circuits 21 that are respectively connected to the first first driving electrode 31 and the third first driving electrode 31 in the first repeat unit 311.

In some examples, with continued reference to FIG. 5A, in the row direction, a dimension of the connection line connected to the third first driving electrode 31 in the second repeat unit 312 is less than a dimension of the connection line connected to the first first driving electrode 31 in the second repeat unit 312.

In some examples, with continued reference to FIG. 5A, in the row direction, a dimension of the connection line connected to the fourth first driving electrode 31 in the second repeat unit 312 is less than a dimension of the connection line connected to the second first driving electrode 31 in the second repeat unit 312.

In some examples, with continued reference to FIG. 5A, in the row direction, the dimension of the connection line connected to the second first driving electrode 31 in the second repeat unit 312 is less than the dimension of the connection line connected to the third first driving electrode 31 in the second repeat unit 312.

It will be noted that, by adopting the above arrangement, it may be possible to make first pixel circuits 21 that are respectively connected to the second first driving electrode 31 and the fourth first driving electrode 31 in the second repeat unit 312 be closer to the first region A1 than first pixel circuits 21 that are respectively connected to the first first driving electrode 31 and the third first driving electrode 31 in the second repeat unit 312.

In the embodiments, by adopting the above arrangement, in a process of the connection lines connected to the first first driving electrode 31 and the third first driving electrode 31 extending, it may be possible to improve regularity of difference in the numbers of first pixel circuits 21 crossed by the connection lines 40, thereby helping improve variation uniformity of parasitic capacitances that are respectively formed by the connection line connected to the first first driving electrode 31 and the connection line connected to the third first driving electrode 31; in a process of the connection lines connected to the second first driving electrode 31 and the fourth first driving electrode 31 extending, it may be possible to improve regularity of difference in the numbers of first pixel circuits 21 crossed by the connection lines 40, thereby helping improve variation uniformity of the parasitic capacitances that are respectively formed by the connection line connected to the second first driving electrode 31 and the connection line connected to the fourth first driving electrode 31. As a result, it ameliorates the brightness difference of “dark-bright-dark” or “bright-dark-bright” caused by uneven variation in parasitic capacitances of the connection lines, and avoids affecting the display effect.

In some examples, in the first direction (i.e., in the row direction), a dimension of the metal connection line 42 that is connected to the second first driving electrode 31 in the first repeat unit 311 is equal to a dimension of the metal connection line 42 that is connected to the fourth first driving electrode 31 in the second repeat unit 312.

It can be understood that, the connection line connected to the second first driving electrode 31 in the first repeat units 311 is the metal connection line 42, and the connection line connected to the fourth first driving electrode 31 in the second repeat unit 312 is the metal connection line 42.

By adopting the above arrangement, it may be possible to enable a difference between a parasitic capacitance formed by the metal connection lines 42 that is connected to the second first driving electrode 31 in the first repeat unit 311 and a parasitic capacitance formed by the metal connection line 42 that is connected to the fourth first driving electrode 31 in the second repeat unit 312 to be relatively small, thereby further improving the display effect of the display panel 100.

In some embodiments, with continued reference to FIG. 5A, the first first driving electrode 31 corresponds to a red sub-pixel region R, the second first driving electrode 31 corresponds to a green sub-pixel region G, the third first driving electrode 31 corresponds to a blue sub-pixel region B, and the fourth first driving electrode 31 corresponds to another green sub-pixel region G.

Based on this, the connection lines 40 that are respectively connected to the first first driving electrode 31 and the third first driving electrode 31 in the first repeat unit 311 extend to the second region A2 through one of two wiring regions 04 adjacent to the row of first driving electrodes 31 in which the first first driving electrode 31 and the third first driving electrode 31 are located, and the connection lines 40 that are respectively connected to the second first driving electrode 31 and the fourth first driving electrode 31 in the first repeat unit 311 extend to the second region A2 through the other one of the two wiring regions 04 adjacent to the row of first driving electrodes 31; and/or the connection lines 40 that are respectively connected to the first first driving electrode 31 and the third first driving electrode 31 in the second repeat unit 312 extend to the second region A2 through one of two wiring regions 04 adjacent to the row of first driving electrodes 31 in which the first first driving electrode 31 and the third first driving electrode 31 are located, and connection lines 40 that are respectively connected to the second first driving electrode 31 and the fourth first driving electrode 31 in the second repeat unit 312 extend to the second region A2 through the other one of the two wiring regions 04 adjacent to the row of first driving electrodes 31. That is, the transparent connection line 41 connected to the first driving electrode 31 corresponding to the green sub-pixel region in the first repeat unit 311 extends to the second region A2 through a different wiring region from transparent connection lines 41 that are respectively connected to the first driving electrode 31 corresponding to the red sub-pixel region in the first repeat unit 311 and the first driving electrode 31 corresponding to the blue sub-pixel region in the first repeat unit 311; and/or the transparent connection line 41 connected to the first driving electrode 31 corresponding to the green sub-pixel region in the second repeat unit 312 extends to the second region A2 through a different wiring region from transparent connection lines 41 that are respectively connected to the first driving electrode 31 corresponding to the red sub-pixel region in the second repeat unit 312 and the first driving electrode 31 corresponding to the blue sub-pixel region in the second repeat unit 312. It helps control the arrangement of wirings connected the first driving electrodes corresponding the green sub-pixel region, the red sub-pixel region and the blue sub-pixel region, and helps ameliorate the problem that the green sub-pixel needs a different charging time from the red sub-pixel and the blue sub-pixel when the sub-pixels need to be lit.

In some embodiments, with continued reference to FIG. 5A, a connection line connected to any one first driving electrode 31, other than first driving electrodes 31 connected to metal connection lines 42, in the at least one row of first driving electrodes 31 is a transparent connection line 41.

In some examples, referring to FIGS. 4A and 4B, the first region A1 includes at least two sub-regions A01 that are sequentially arranged in a set direction. The set direction is a direction directed from the alignment center b of the plurality of light-emitting repeat units 310 to any one end b′ of the plurality of light-emitting repeat units 310 in the first direction (e.g., the direction b-b′ shown in FIGS. 4A and 4B). Transparent connection lines 41 connected to first driving electrodes 31 that are located in different sub-regions A01 are located in different layers.

It can be understood by those skilled in the art that, the description that “the transparent connection lines 41 connected to the first driving electrodes 31 that are located in different sub-regions A01 are located in different layers” means that the transparent connection lines 41 connected to the first driving electrodes 31 that are located in different sub-regions A01 are located in different transparent conductive layers 4 in the thickness direction of the display panel 100 (e.g., the direction a-a′ shown in FIG. 2).

In some examples, the first region A1 includes two sub-regions A01 in the direction b-b′ directed from the alignment center b of the plurality of light-emitting repeat units 310 to any one end b′ of the plurality of light-emitting repeat units 310 in the first direction. Transparent connection lines 41 connected to first driving electrodes 31 that are located in the two sub-regions A01 are located in different layers.

In some examples, referring to FIGS. 4A and 4B, in the direction b-b′ directed from the alignment center b of the plurality of light-emitting repeat units 310 to any one end b′ of the plurality of light-emitting repeat units 310 in the first direction, the at least two sub-regions A01 include a first sub-region A011, a second sub-region A012 and a third sub-region A013. Transparent connection lines 41 connected to first driving electrodes 31 that are located in the three sub-regions A01 are located in different layers.

It can be understood by those skilled in the art that, transparent connection lines 41 connected to the at least one row of first driving electrodes 31 are located in different layers, which means that the transparent connection lines 41 connected to the at least one row of first driving electrodes 31 are located in different transparent conductive layers 4 in the thickness direction of the display panel 100 (e.g., the direction a-a′ shown in FIG. 2).

For example, in the direction b-b′ directed from the alignment center b of the plurality of light-emitting repeat units 310 to any one end b′ of the plurality of light-emitting repeat units 310 in the first direction, transparent connection lines 41 connected to first driving electrodes 31 in the first sub-region A011 are located in the first transparent conductive layer 041, transparent connection lines 41 connected to first driving electrodes 31 in the second sub-region A012 are located in the second transparent conductive layer 042, and transparent connection lines 41 connected to first driving electrodes 31 in the third sub-region A013 are located in the third transparent conductive layer 043.

In some examples, in the at least one row of the first driving electrodes 31, the numbers of first driving electrodes 31, connected to transparent connection lines 41, in different sub-regions A01 are unequal. In some other examples, in the at least one row of the first driving electrodes 31, the numbers of first driving electrodes 31, connected to the transparent connection lines 41, in different sub-regions A01 are equal. The embodiments of the present disclosure are not limited to this.

For example, in the first sub-region A011, the second sub-region A012 and the third sub-region A013, the numbers of the first driving electrodes 31 connected to the transparent connection lines 41 each are 13.

On this basis, a connection line connected to the first driving electrode 31 that corresponds to a green sub-pixel region G in the third sub-region A13 is a metal connection line 42. In this case, the number of first driving electrodes 31 in the third sub-region A013 is 14: the number of first driving electrodes 31 in the first sub-region A011 and the number of first driving electrodes 31 in the second sub-region A012 are both 13.

In this case, the number of first driving electrodes 31 corresponding to green sub-pixel regions G in the third sub-region A013 is 7, the number of first driving electrodes 31 corresponding to green sub-pixel regions G in the second sub-region A012 is 6, and the number of first driving electrodes 31 corresponding to green sub-pixel regions G in the first sub-region A011 is 7.

In some examples, in each row of first driving electrodes 31 in the first region A1, the numbers of first driving electrodes 31 in different sub-regions A01 are equal. In some other examples, in each row of first driving electrodes 31 in the first region A1, the numbers of first driving electrodes 31 in different sub-regions A01 are unequal. The embodiments of the present disclosure are not limited to this.

In the examples, for some or all of rows of first driving electrodes 31, the numbers of first driving electrodes 31 in different sub-regions A01 are equal. That is, for some or all of the rows of first driving electrodes 31, the numbers of transparent connection lines 41 extending from different sub-regions A01 are equal. It may make the wiring path planning for the transparent connection lines 41 more regular, thereby simplifying the structure of the display panel 100, and reducing the difficulty in fabrication of the display panel 100.

In some examples, referring to FIGS. 4A and 4B, in the first repeat unit 311, the first driving electrode 31 connected to the metal connection line 42 is located in a sub-region, farthest away from the alignment center b of the plurality of light-emitting repeat units 310, in the at least two sub-regions A01 that are sequentially arranged in the direction directed from the alignment center b of the plurality of light-emitting repeat units 310 to one end b′ of the plurality of light-emitting repeat units 310 in the first direction: in the second repeat unit 312, the first driving electrode 31 connected to the metal connection line 42 is located in a sub-region, farthest away from the alignment center b of the plurality of light-emitting repeat units 310, in the at least two sub-regions A01 that are sequentially arranged in the direction directed from the alignment center b of the plurality of light-emitting repeat units 310 to the other end b′ of the plurality of light-emitting repeat units 310 in the first direction.

For example, in the case where the at least two sub-regions include the first sub-region A011, the second sub-region A012 and the third sub-region A013, as shown in FIG. 4B, the first driving electrode 31 connected to the metal connection line 42 in the first repeat unit 311 is located in the third sub-region A013, and the first driving electrode 31 connected to the metal connection line 42 in the second repeat unit 312 is located in the another third sub-region A013.

In the embodiments, the first region A1 includes the at least two sub-regions A01 that are sequentially arranged in the set direction, and the transparent connection lines 41 connected to the first driving electrodes 31 located in different sub-regions A01 are located in different layers. As a result, it increases the arrangement space for the connection lines 40 that are electrically connected to the row of first driving electrodes 31, thereby achieving the arrangement of the large number of transparent connection lines 41 in the limited space. In addition, the transparent connection lines 41 each may extend to the second region A2 through the wiring region 04, and the transparent connection lines 41 are regularly arranged, which may improve regularity of difference in the numbers of first pixel circuits 21 and/or second pixel circuits 22 crossed by transparent connection lines 41 that are connected to first driving electrodes 31 in any two adjacent sub-regions. As a result, it helps improve variation uniformity of parasitic capacitances that are formed by the transparent connection lines 41 connected to the first driving electrodes 31 in two adjacent sub-regions, and increase the accuracy of driving signals received by the first driving electrodes 31. A wiring environment of the transparent connection lines 41 are uniform, which may ameliorate the brightness difference of the display panel 100, and improve the display effect of the display panel 100.

In some embodiments, with continued reference to FIG. 4A, for connection lines 40 connected to W first driving electrodes 31 that are closest to the alignment center b of the plurality of light-emitting repeat units 310 in the plurality of light-emitting repeat units 310, the connection line 40 includes a first wiring segment 401, a second wiring segment 402 and a third wiring segment 403 that are connected in sequence.

In some examples, the first wiring segment 401 and the third wiring segment 403 extend in the first direction and are located in different wiring regions 04, and the second wiring segment 402 extends in the second direction.

W is a positive integer greater than or equal to 1 and less than or equal to 5. The second wiring segment 402 is located in any one of the first sub-region A011, the second sub-region A012 and the third sub-region A013.

Thus, the connection lines 40 connected to the W first driving electrodes 31 that are closest to the alignment center b of the plurality of light-emitting repeat units 310 extends to the second region A2, which achieves the electrical connection of the first driving electrode 31 and the first pixel circuit 21.

In some embodiments, any one light-emitting repeat unit 310 includes a first first driving electrode 31 to a fourth first driving electrode 31 that are sequentially arranged in the second set direction b-c′.

In some examples, connection lines that are respectively connected to the first first driving electrode 31 and a third first driving electrode 31 in any one light-emitting repeat unit 310 extend to the second region A2 through one of two wiring regions 04 that are adjacent to a row of first driving electrodes 31 in which the first first driving electrode 31 and the third first driving electrode 31 are located.

In some examples, connection lines that are respectively connected to a second first driving electrode 31 and the fourth first driving electrode 31 in any one light-emitting repeat unit 310 extend to the second region A2 through the other one of the two wiring regions 04 that are adjacent to the row of first driving electrodes 31.

By adopting the above arrangement, it is easy to control the wiring arrangement of connection lines connected to first first driving electrodes 31 and third first driving electrodes 31 in all light-emitting repeat units 310 in a row, and connection lines connected to second first driving electrodes 31 and fourth first driving electrodes 31 in all light-emitting repeat units 310 in the row.

Based on this, the first first driving electrode 31 corresponds to a red sub-pixel region R, the second first driving electrode 31 corresponds to a green sub-pixel region G, the third first driving electrode 31 corresponds to a blue sub-pixel region B, and the fourth first driving electrode 31 corresponds to another green sub-pixel region G. That is, the transparent connection line 41 connected to the first driving electrode 31 that corresponds to the green sub-pixel region extends to the second region A02 through a different wiring region from the transparent connection lines 41 connected to the first driving electrode 31 that corresponds to the red sub-pixel region and the first driving electrode 31 that corresponds to the blue sub-pixel region. It helps control the arrangement of wirings connected the first driving electrodes corresponding the green sub-pixel region, the red sub-pixel region and the blue sub-pixel region, and helps ameliorate the problem that the green sub-pixel needs a different charging time from the red sub-pixel and the blue sub-pixel when the sub-pixels need to be lit.

In some embodiments, with continued reference to FIG. 5A, in the row direction, a dimension of a connection line 40 connected to any one of the first first driving electrode 31 and the third first driving electrode 31 is greater than a dimension of a connection line 40 connected to any one of the second first driving electrode 31 and the fourth first driving electrode 31.

It will be noted that, the description that “in the row direction, the dimension of the connection line 40 connected to any one of the first first driving electrode 31 and the third first driving electrode 31 is greater than the dimension of the connection line 40 connected to any one of the second first driving electrode 31 and the fourth first driving electrode 31” may mean that, the dimension of the connection line 40 connected to any one of the first first driving electrode 31 and the third first driving electrode 31 in any one light-emitting repeat unit 310 is greater than the dimension of the connection line 40 connected to any one of the second first driving electrode 31 and the fourth first driving electrode 31, or may mean that, the dimension of the connection line 40 connected to any one of first first driving electrodes 31 and third first driving electrodes 31 in a row of light-emitting repeat unit 310 is greater than the dimension of the connection line 40 connected to any one of second first driving electrodes 31 and fourth first driving electrodes 31.

By adopting the above arrangement, it may be possible to make first pixel circuits 21 connected to the second first driving electrode 31 and the fourth first driving electrode 31 closer to the first region A1 than first pixel circuits 21 connected to the first first driving electrode 31 and the third first driving electrode 31.

On this basis, the first first driving electrode 31 corresponds to a red sub-pixel region R, the second first driving electrode 31 corresponds to a green sub-pixel region G, the third first driving electrode 31 corresponds to a blue sub-pixel region B, and the fourth first driving electrode 31 corresponds to another green sub-pixel region G. That is, the connection line connected to the green sub-pixel is shorter than the connection lines that are respectively connected to the red sub-pixel and the blue sub-pixel. For example, the first pixel circuit corresponding to the green sub-pixel is closer to the first region A1 than the first pixel circuit corresponding to the red sub-pixel and the first pixel circuit corresponding to the blue sub-pixel.

Thus, by making the connection line connected to the green sub-pixel shorter than the connection lines that are connected to the red sub-pixel and the blue sub-pixel, it reduces the parasitic capacitance of the connection line connected to the green sub-pixel. In the same time, the charging time of the green sub-pixel is long, and thus the green sub-pixel has a full amount of charge, and is easy to be lit. As a result, the display effect of the display panel is improved.

In some examples, all the first driving electrodes 31 are divided into a plurality of first basic units, a first basic unit includes 1k row(s) and 2h columns of first driving electrodes. K and h are positive integers greater than or equal to 1. For example, the first basic unit may include one row and two columns of first driving electrodes, two rows and four columns of first driving electrodes, or four rows and eight columns of first driving electrodes. Thus, the 1k row(s) and 2h columns of first driving electrodes constitute the basic unit, which may be matched to the algorithm.

Thus, all first driving electrodes 31 in the first region A1 may adopt the same display algorithm to perform display, and the second region A2 adopts a display algorithm different from the first region A1 to perform display. As a result, it ensures that the second region A2 and the first region A1 each are capable of rendering color accurately after being processed by respective display algorithms, avoids the color shifting problem caused by the two regions adopting the same display algorithm for display, and weakens the sawtooth phenomenon happened to edges of the first region A1 and the second region A2 when display is performed, thereby helping improve the display uniformity of the display panel 100, and improving the quality of the image displayed by the display panel 100.

In some embodiments, with continued reference to FIGS. 4A to 4C, 4E, and 5A to 6, the transparent connection lines 41 connected to the at least one row of first driving electrodes 31 extend to the second region A2 through at least two wiring regions 04. An end of a transparent connection line 41 is electrically connected to a first driving electrode 31 in a row of first driving electrodes 31, and the other end of the transparent connection line 41 is electrically connected to a corresponding first pixel circuit 21 in the second region A2. Thus, the electrical connection between the first pixel circuit 21 and the corresponding first driving electrode 31 may be achieved by using the transparent connection line 41, so that the first pixel circuit 21 may transmit the driving signal to the corresponding first driving electrode 31 through the transparent connection line 41.

It will be noted that, the description that “the transparent connection lines 41 connected to the at least one row of first driving electrodes 31 extend to the second region A2 through the at least two wiring regions 04” may mean that the transparent connection lines 41 connected to the at least one row of first driving electrodes 31 extend to the second region A2 through two wiring regions 04, or may mean that the transparent connection lines 41 connected to the at least one row of first driving electrodes 31 extend to the second region A2 through three or more wiring regions 04. The embodiments of the present disclosure are not limited to this. For example, as shown in FIG. 4C, the transparent connection lines 41 connected to the at least one row of first driving electrodes 31 extend to the second region A2 through three wiring regions 04; or as shown in FIGS. 4A and 4B, the transparent connection lines 41 connected to the at least one row of first driving electrodes 31 extend to the second region A2 through two wiring regions 04.

In the embodiments, the first driving electrode 31 is electrically connected to the corresponding first pixel circuit 21 in the second region A2 through the transparent connection line 41, so that the first pixel circuit 21 may transmit the driving signal to the corresponding first driving electrode 31 through the transparent connection line 41; in addition, it may reduce the blocking of light, so that the light can pass through a gap between any two adjacent first driving electrodes 31 from a side (e.g., the light exit side) of the portion of the display panel 100 in the first region A1, and then exit from another side (e.g., the non-light exit side) of the portion of the display panel 100 in the first region A1. As a result, the portion of the display panel 100 in the first region A1 has a relatively high light transmittance.

On this basis, the transparent connection lines 41 connected to the at least one row of first driving electrodes 31 are arranged in different layers, which may increase the arrangement space for transparent connection lines 41 that are electrically connected to a row of first driving electrodes 31. As a result, it achieves the arrangement of the large number of transparent connection lines 41 in the limited space, and enables the first driving electrodes 31 to be connected to the first pixel circuits 21 in one-to-one correspondence through the transparent connection lines 41.

In some other embodiments, referring to FIGS. 4C and 8, the transparent connection lines 41 connected to the at least one row of first driving electrodes 31 include first-type transparent connection lines 411 and second-type transparent connection lines 412.

In some examples, with continued reference to FIG. 8, transparent connection lines 41 connected to a 004-th row of first driving electrodes 31 includes first-type transparent connection lines 411 and second-type transparent connection lines 412; transparent connection lines 41 connected to a 007-th row of first driving electrodes 31 includes first-type transparent connection lines 411 and second-type transparent connection lines 412; transparent connection lines 41 connected to a 008-th row of first driving electrodes 31 includes first-type transparent connection lines 411 and second-type transparent connection lines 412; transparent connection lines 41 connected to a 010-th row of first driving electrodes 31 includes first-type transparent connection lines 411 and second-type transparent connection lines 412; transparent connection lines 41 connected to a 011-th row of first driving electrodes 31 includes first-type transparent connection lines 411 and second-type transparent connection lines 412; and transparent connection lines 41 connected to a 013-th row of first driving electrodes 31 includes first-type transparent connection lines 411 and second-type transparent connection lines 412.

It will be noted that the description is merely an example, and those skilled in the art can understand that transparent connection lines 41 connected to other row of first driving electrodes 31 may also include first-type transparent connection lines 411 and second-type transparent connection lines 412.

In a row of first driving electrodes 31, a first driving electrode 31 electrically connected to the first-type transparent connection line 411 is closer to a center of the row of first driving electrodes 31 than a first driving electrode 31 electrically connected to the second-type transparent connection line 412.

In some examples, with continued reference to FIG. 8, the number of first-type transparent connection lines 411 is greater than the number of second-type transparent connection lines 412, and the first-type transparent connection lines 411 and the second-type transparent connection lines 412 are located in different layers.

It can be understood by those skilled in the art that, the description that “the first-type transparent connection lines 411 and the second-type transparent connection lines 412 are located in different layers” means that the first-type transparent connection lines 411 and the second-type transparent connection lines 412 are located in different transparent conductive layers 4 in the thickness direction of the display panel 100 (e.g., the direction a-a′ shown in FIG. 2).

In the embodiments, by arranging the transparent connection lines 41 connected to the at least one row of first driving electrodes 31 in different layers, it may be possible to increase the arrangement space for the transparent connection lines 41 that are electrically connected to a row of first driving electrodes 31. As a result, it achieves the arrangement of the large number of connection lines 40 in the limited space, and it avoids the problem that some of the first driving electrodes 31 fail to be electrically connected to respective first pixel circuits 21 through connection lines 40 due to arrangement of a lot of connection lines 40 in the same layer in a case where the number of first driving electrodes 31 in the row of first driving electrodes 31 are large.

In some embodiments, referring to FIG. 4C, the first-type transparent connection lines 411 connected to the at least one row of first driving electrodes 31 extend to the second region A2 through N1 wiring regions 04 that are located on a same side of the row of first driving electrodes 31 and close to the row of first driving electrodes 31. N1 is a positive integer greater than or equal to 2.

For example, as shown in FIG. 4C, N1 is equal to 3 (N1=3). The first-type transparent connection lines 411 connected to the at least one row of first driving electrodes 31 extend to the second region A2 through three wiring regions 04 that are located on the same side of the row of first driving electrodes 31 and close to the row of first driving electrodes 31.

In the embodiments, the first-type transparent connection lines 411 connected to the at least one row of first driving electrodes 31 are located in the N1 wiring regions 04, which may increase the arrangement space for the connection lines 40 that are electrically connected to the row of first driving electrodes 31. Thus, it achieves the arrangement of the large number of connection lines 40 in the limited space, and enables the first driving electrodes 31 to be connected to the first pixel circuits 21 in one-to-one correspondence through the transparent connection lines 41. As a result, the first pixel circuits 21 may transmit the driving signals to respective first driving electrodes 31 through the first-type transparent connection lines 411.

In some embodiments, adjacent N2 rows of first driving electrodes 31 are set as a cycle. N2 is a positive integer greater than or equal to 2. First-type transparent connection lines 411 connected to each row of first driving electrodes 31 in the same cycle are located in a different layer.

In some examples, referring to FIG. 8, N2 is equal to 3 (N2=3). A 001-st row of first driving electrodes 31, a 002-nd row of first driving electrodes 31 and a 003-rd row of first driving electrodes 31 that are adjacent are set as a cycle 01. The 004-th row of first driving electrodes 31, a 005-th row of first driving electrodes 31 and a 006-th row of first driving electrodes 31 that are adjacent are set as another cycle 01. The 007-th row of first driving electrodes 31, the 008-th row of first driving electrodes 31 and a 009-th row of first driving electrodes 31 that are adjacent are set as yet another cycle 01. The 010-th row of first driving electrodes 31, the 011-th row of first driving electrodes 31 and a 012-th row of first driving electrodes 31 that are adjacent are set as yet another cycle 01. The 013-th row of first driving electrodes 31, the 014-th row of first driving electrodes 31 and a 015-th row of first driving electrodes 31 that are adjacent are set as yet another cycle 01.

First-type transparent connection lines 411 connected to three rows of first driving electrodes 31 in a same cycle are located in different layers.

For example, with continued reference to FIG. 8, transparent connection lines 41 connected to the 001-st row of first driving electrodes 31 include first-type transparent connection lines 411, transparent connection lines 41 connected to the 002-nd row of first driving electrodes 31 include first-type transparent connection lines 411, and transparent connection lines 41 connected to the 003-rd row of first driving electrodes 31 include first-type transparent connection lines 411. The first-type transparent connection lines 411 connected to the 001-st row of first driving electrodes 31, the first-type transparent connection lines 411 connected to the 002-nd row of first driving electrodes 31 and the first-type transparent connection lines 411 connected to the 003-rd row of first driving electrodes 31 are located in different layers.

Similarly, first-type transparent connection lines 411 connected to the 004-th row of first driving electrodes 31, first-type transparent connection lines 411 connected to the 005-th row of first driving electrodes 31 and first-type transparent connection lines 411 connected to the 006-th row of first driving electrodes 31 are located in different layers.

Similarly, first-type transparent connection lines 411 connected to the 007-th row of first driving electrodes 31, first-type transparent connection lines 411 connected to the 008-th row of first driving electrodes 31 and first-type transparent connection lines 411 connected to the 009-th row of first driving electrodes 31 are located in different layers.

Similarly, first-type transparent connection lines 411 connected to the 010-th row of first driving electrodes 31, first-type transparent connection lines 411 connected to the 011-th row of first driving electrodes 31 and first-type transparent connection lines 411 connected to the 012-th row of first driving electrodes 31 are located in different layers.

Similarly, first-type transparent connection lines 411 connected to the 013-th row of first driving electrodes 31, first-type transparent connection lines 411 connected to the 014-th row of first driving electrodes 31 and first-type transparent connection lines 411 connected to the 015-th row of first driving electrodes 31 are located in different layers.

It can be understood by those skilled in the art that, the description that “the first-type transparent connection lines 411 connected to three rows of first driving electrodes 31 in the same cycle are located in different layers” means that the first-type transparent connection lines 411 connected to three rows of first driving electrodes 31 in the same cycle are located in different transparent conductive layers 4 in the thickness direction of the display panel 100 (e.g., the direction a-a′ shown in FIG. 2).

In the embodiments, by arranging the first-type transparent connection lines 411 connected to the rows of first driving electrodes 31 in the same cycle to be in different layers, it may be possible to increase the wiring space for the first-type transparent connection lines 411 connected to each row of first driving electrodes 31. As a result, it achieves the arrangement of the large number of transparent connection lines in the limited space, prevents a short circuit between the first-type transparent connection lines 411 in a case where a lot of first-type transparent connection lines 411 are arranged in the same layer, and reduces the difficulty of structural design and process.

In some embodiments, at least part of second-type transparent connection lines 412 connected to the at least one row of first driving electrodes 31 are arranged in a same layer as first-type transparent connection lines 411 connected to any one row of first driving electrodes 31 that are located in a same cycle 01 as the row of first driving electrodes 31, and extend to the second region A2 through a wiring region 04 where first-type transparent connection lines 411 are located, the first-type transparent connection lines 411 being connected to the first driving electrodes 31 that are located in the same cycle as the row of the first driving electrodes 31.

In some examples, referring to FIG. 8, transparent connection lines 41 connected to the 004-th row of first driving electrodes 31 include the first-type transparent connection lines 411 and the second-type transparent connection lines 412. The second-type transparent connection lines 412 connected to the 004-th row of first driving electrodes 31 may include first partial transparent connection lines 4121 and second partial transparent connection lines 4122. The first partial transparent connection lines 4121 connected to the 004-th row of first driving electrodes 31 may be arranged in a same layer as the first-type transparent connection lines 411 connected to the 005-th row of first driving electrodes 31, and extend to the second region A2 through a wiring region 04 where the first-type transparent connection lines 411 connected to the 005-th row of first driving electrodes 31 are located.

Similarly, transparent connection lines 41 connected to the 007-th row of first driving electrodes 31 include the first-type transparent connection lines 411 and the second-type transparent connection lines 412. The second-type transparent connection lines 412 connected to the 007-th row of first driving electrodes 31 may include first partial transparent connection lines 4121 and second partial transparent connection lines 4122. The first partial transparent connection lines 4121 connected to the 007-th row of first driving electrodes 31 may be arranged in a same layer as the first-type transparent connection lines 411 connected to the 008-th row of first driving electrodes 31, and extend to the second region A2 through a wiring region 04 where the first-type transparent connection lines 411 connected to the 008-th row of first driving electrodes 31 are located.

Similarly, transparent connection lines 41 connected to the 008-th row of first driving electrodes 31 include the first-type transparent connection lines 411 and the second-type transparent connection lines 412. At least part of the second-type transparent connection lines 412 connected to the 008-th row of first driving electrodes 31 may be arranged in a same layer as the first-type transparent connection lines 411 connected to the 009-th row of first driving electrodes 31, and extend to the second region A2 through a wiring region 04 where the first-type transparent connection lines 411 connected to the 009-th row of first driving electrodes 31 are located.

Similarly, transparent connection lines 41 connected to the 010-th row of first driving electrodes 31 include the first-type transparent connection lines 411 and the second-type transparent connection lines 412. At least part of the second-type transparent connection lines 412 connected to the 010-th row of first driving electrodes 31 may be arranged in a same layer as the first-type transparent connection lines 411 connected to the 012-th row of first driving electrodes 31, and extend to the second region A2 through a wiring region 04 where the first-type transparent connection lines 411 connected to the 012-th row of first driving electrodes 31 are located.

Similarly, transparent connection lines 41 connected to the 011-th row of first driving electrodes 31 include the first-type transparent connection lines 411 and the second-type transparent connection lines 412. At least part of the second-type transparent connection lines 412 connected to the 011-th row of first driving electrodes 31 may be arranged in a same layer as the first-type transparent connection lines 411 connected to the 012-th row of first driving electrodes 31, and extend to the second region A2 through the wiring region 04 where the first-type transparent connection lines 411 connected to the 012-th row of first driving electrodes 31 are located.

Similarly, transparent connection lines 41 connected to the 013-th row of first driving electrodes 31 include the first-type transparent connection lines 411 and the second-type transparent connection lines 412. At least part of the second-type transparent connection lines 412 connected to the 013-th row of first driving electrodes 31 may be arranged in a same layer as the first-type transparent connection lines 411 connected to the 015-th row of first driving electrodes 31, and extend to the second region A2 through a wiring region 04 where the first-type transparent connection lines 411 connected to the 015-th row of first driving electrodes 31 are located.

It will be noted that, the “same layer” refers to a layer structure formed by forming a film layer for forming a specific pattern through a same film forming process and then performing a single patterning process using a same mask. Depending on different specific patterns, the patterning process may include exposure processes, development processes or etching processes, the specific patterns in the formed layer structure may be continuous or discontinuous, and these specific patterns may also be at different heights or have different thicknesses.

In the embodiments, by arranging the at least part of the second-type transparent connection lines 412 connected to the at least one row of first driving electrodes 31 to be in the same layer as the first-type transparent connection lines 411 connected to any one row of first driving electrodes 31 that are located in the same cycle 01 as the row of first driving electrodes 31, it not only simplifies the fabrication process, but may also make up for the arrangement space for first-type transparent connection lines 411 electrically connected to a row with a large number of first driving electrodes 31 through a row with a small number of first driving electrodes 31 that is in a same cycle as the row with the large number of first driving electrodes 31, and increase the arrangement space for the first-type transparent connection lines 411 electrically connected to the row with the large number of first driving electrodes 31 in the same cycle, thereby achieving the arrangement of the large number of first-type transparent connection lines 411 in the limited space.

In some embodiments, at least part of second-type transparent connection lines 412 connected to the at least one row of first driving electrodes 31 are arranged in a same layer as first-type transparent connection lines 411 connected to any one row of first driving electrodes 31 that are located in a different cycle from the row of first driving electrodes 31, and extend to the second region A2 through a wiring region 04 where first-type transparent connection lines 411 are located, the first-type transparent connection lines 411 being connected to the first driving electrodes 31 in the different cycle from the row of the first driving electrodes 31.

In some examples, referring to FIG. 8, transparent connection lines 41 connected to the 004-th row of first driving electrodes 31 include the first-type transparent connection lines 411 and the second-type transparent connection lines 412. The second-type transparent connection lines 412 connected to the 004-th row of first driving electrodes 31 may include the first partial transparent connection lines 4121 and the second partial transparent connection lines 4122. The second partial transparent connection lines 4122 connected to the 004-th row of first driving electrodes 31 may be arranged in a same layer as the first-type transparent connection lines 411 connected to the 003-rd row of first driving electrodes 31, and extend to the second region A2 through a wiring region 04 where the first-type transparent connection lines 411 connected to the 003-rd row of first driving electrodes 31 are located.

Similarly, transparent connection lines 41 connected to the 007-th row of first driving electrodes 31 include the first-type transparent connection lines 411 and the second-type transparent connection lines 412. The second-type transparent connection lines 412 connected to the 007-th row of first driving electrodes 31 may include the first partial transparent connection lines 4121 and the second partial transparent connection lines 4122. The second partial transparent connection lines 4122 connected to the 007-th row of first driving electrodes 31 may be arranged in a same layer as the first-type transparent connection lines 411 connected to the 006-th row of first driving electrodes 31, and extend to the second region A2 through a wiring region 04 where the first-type transparent connection lines 411 connected to the 006-th row of first driving electrodes 31 are located.

Similarly, transparent connection lines 41 connected to the 010-th row of first driving electrodes 31 include the first-type transparent connection lines 411 and the second-type transparent connection lines 412. At least part of the second-type transparent connection lines 412 connected to the 010-th row of first driving electrodes 31 may be arranged in a same layer as the first-type transparent connection lines 411 connected to the 009-th row of first driving electrodes 31, and extend to the second region A2 through a wiring region 04 where the first-type transparent connection lines 411 connected to the 009-th row of first driving electrodes 31 are located.

Similarly, transparent connection lines 41 connected to the 013-th row of first driving electrodes 31 include the first-type transparent connection lines 411 and the second-type transparent connection lines 412. At least part of the second-type transparent connection lines 412 connected to the 013-th row of first driving electrodes 31 may be arranged in a same layer as the first-type transparent connection lines 411 connected to the 012-th row of first driving electrodes 31, and extend to the second region A2 through a wiring region 04 where the first-type transparent connection lines 411 connected to the 012-th row of first driving electrodes 31 are located.

In the embodiments, by arranging the at least the part of the second-type transparent connection lines 412 connected to the at least one row of first driving electrodes 31 to be arranged in the same layer as the first-type transparent connection lines 411 connected to any one row of first driving electrodes 31 that are located in the different cycle from the row of first driving electrodes 31, it not only simplifies the fabrication process, but may also make up for the arrangement space for first-type transparent connection lines 411 electrically connected to a row with a large number of first driving electrodes 31 in other cycle through a row with a small number of first driving electrodes 31 in a cycle different from the other cycle, and increase the arrangement space for the first-type transparent connection lines 411 electrically connected to the row with the large number of first driving electrodes 31, thereby achieving the arrangement of the large number of first-type transparent connection lines 411 in the limited space.

In some other embodiments, the transparent connection lines 41 connected to a row of first driving electrodes 31 extend to the second region A02 through one or both of the wiring regions 04 adjacent to the row of first driving electrodes 31.

In some examples, the transparent connection lines 41 connected to the row of first driving electrodes 31 extend to the second region A02 through one of the wiring regions 04 adjacent to the row of first driving electrodes 31.

In some other examples, as shown in FIGS. 4A and 4B, the transparent connection lines 41 connected to the row of first driving electrodes 31 extend to the second region A02 through both of the wiring regions 04 adjacent to the row of first driving electrodes 31.

In the embodiments, the transparent connection lines 41 connected to the row of first driving electrodes 31 extend to the second region A02 through one or both of the wiring regions 04 adjacent to the row of first driving electrodes 31, which may increase the arrangement space for the transparent connection lines 41 electrically connected to the row of the first driving electrodes 31. As a result, it achieves the arrangement of the large number of transparent connection lines 41 in the limited space, and enables the first driving electrodes 31 to be connected to the first pixel circuits 21 in one-to-one correspondence through the transparent connection lines 41.

In addition, in the case where the transparent connection lines 41 connected to the row of first driving electrodes 31 extend to the second region A02 through both of the wiring regions 04 adjacent to the row of first driving electrodes 31, the transparent connection line 41 connected to the first driving electrode 31 corresponding to the green sub-pixel region extends to the second region A02 through a different wiring region from the transparent connection lines 41 that are respectively connected to the first driving electrode 31 corresponding to the red sub-pixel region and the first driving electrode 31 corresponding to the blue sub-pixel region, which helps control the arrangement of wirings connected the first driving electrodes corresponding the green sub-pixel region, the red sub-pixel region and the blue sub-pixel region, and helps ameliorate the problem that the green sub-pixel needs a different charging time from the red sub-pixel and the blue sub-pixel when the sub-pixels need to be lit.

In some embodiments, with continued reference to FIGS. 4D and 4E, the first region A1 further includes edge regions A02. An edge region A02 is located between the at least two sub-regions A01 and the second region A2 in the set direction.

In some examples, with continued reference to FIGS. 4A to 8, at least part of the plurality of connection lines 40 are metal connection lines 42. The metal connection lines 42 may be located in the first source-drain electrode layer 201 or the second source-drain electrode layer 202.

In some examples, at least connection lines connected to first driving electrodes 31 that correspond to green sub-pixel regions in the edge region A02 are metal connection lines 42.

It will be noted that connection lines connected to first driving electrodes 31 that correspond to red sub-pixel regions in the edge region A02 and first driving electrodes 31 that correspond to blue sub-pixel regions in the edge region A02 may be metal connection lines 42 or transparent connection lines 41, and the embodiments of the present disclosure are not limited thereto.

In some examples, the metal connection lines 42 connected to the first driving electrodes 31 in the edge region A02 and metal connection lines 42 connected to first driving electrodes 31 in the first region A1 are arranged in different layers.

For example, the metal connection lines 42 connected to the first driving electrodes 31 in the edge region A02 are located in the second source-drain electrode layer 202, and the metal connection lines 42 connected to the first driving electrodes 31 in the first region A1 are located in the first source-drain electrode layer 201; or the metal connection lines 42 connected to the first driving electrodes 31 in the edge region A02 are located in the first source-drain electrode layer 201, and the metal connection lines 42 connected to the first driving electrodes 31 in the first region A1 are located in the second source-drain electrode layer 202. The embodiments of the present disclosure are not limited to this.

In the embodiments, at least the connection lines connected to the first driving electrodes 31 that correspond to the green sub-pixel regions in the edge region A02 are the metal connection lines 42, which makes up for the arrangement space for the connection lines 40 electrically connected to the row of the first driving electrodes 31, and increases the arrangement space for the connection lines 40 electrically connected to the row of the first driving electrodes 31, and thus achieves the arrangement of the large number of connection lines 40 in the limited space.

In some embodiments, in the row of first driving electrodes 31, the number of first driving electrodes 31 electrically connected to the metal connection lines 42 does not exceed a first threshold. The first threshold is in a range of 2 to 5, inclusive. For example, the number of the first driving electrodes 31 electrically connected to the metal connection lines 42 may be 2, 3, 4 or 5.

In some examples, with continued reference to FIG. 8, in the 001-st row of first driving electrodes 31, the number of the first driving electrodes 31 electrically connected to the metal connection lines 42 is two.

In the embodiments, in the row of first driving electrodes 31, the number of first driving electrodes 31 electrically connected to the metal connection lines 42 does not exceed the range of 2 to 5, which may make up for the arrangement space for the connection lines 40 electrically connected to the row of first driving electrodes 31, and increase the arrangement space for the connection lines 40 electrically connected to the row of first driving electrodes 31; in addition, the number of the metal connection lines 42 is relatively small, which avoids a short circuit between metal connection lines 42 that are in a same layer, and reduces the difficulty of structural design and process.

In some other embodiments, with continued reference to FIGS. 5B and 6, in the connection lines 40 connected to the row of first driving electrodes 31, a length of the metal connection line 42 is smaller than a length of the transparent connection line 41.

In the embodiments, the metal connection line 42 has the relatively small length, so that the parasitic capacitance between the metal connection line 42 and an entire layer of the display panel 100 is relatively small. It may prevent parasitic capacitance jump between the metal connection line 42 and the transparent connection line 41, thereby ameliorating the display image flicker caused by the parasitic capacitance jump, improving the display uniformity in the first region A1 and the second region A2, and improving the quality of the image displayed by the display panel 100.

In some embodiments, referring to FIG. 6, the farther a first driving electrode 31 is away from the center of the row of first driving electrodes 31, the shorter a metal connection line 42 connected to the first driving electrode 31 is.

In this case, the description that “the farther the first driving electrode 31 is away from the center of the row of first driving electrodes 31, the shorter the metal connection line 42 connected to the first driving electrode 31 is” means that, the farther the first driving electrode 31 is away from the center of the row of first driving electrodes 31, the smaller length the metal connection line 42 connected to the first driving electrode 31 has. For example, the length of the metal connection line 42 refers to the dimension of the metal connection line 42 in the first direction X.

In some other embodiments, referring to FIG. 6, the farther a first driving electrode 31 is away from the center of the row of first driving electrodes 31, the shorter a transparent connection line 41 connected to the first driving electrode 31 is.

In this case, the description that “the farther the first driving electrode 31 is away from the center of the row of first driving electrodes 31, the shorter the transparent connection line 41 connected to the first driving electrode 31 is” means that, the farther the first driving electrode 31 is away from the center of the row of first driving electrodes 31, the smaller length the transparent connection line 41 connected to the first driving electrode 31 has. For example, the length of the transparent connection line 41 refers to a dimension of the transparent connection line 41 in the first direction X.

Thus, it may improve regularity of difference in the numbers of first pixel circuits 21 crossed by any two adjacent connection lines 40 in the connection lines 40 in a process of the connection lines 40 extending, thereby helping improve variation uniformity of the parasitic capacitances that are respectively formed by any two adjacent connection lines.

In some other embodiments, a row of first pixel circuits 21 and a row of first driving electrodes 31 are electrically connected in a manner where a first pixel circuit 21 and a first driving electrode 31 that are close to each other are connected, and a first pixel circuit 21 and a first driving electrode 31 that are gradually far away from each other are connected.

For example, a row of first driving electrodes 31 includes a first first driving electrode 31 to an N-th first driving electrode 31 in a direction directed from the second region A2 to a center of the first region A1 along the first direction X. On a side of the first region A1, a row of first pixel circuits 21 includes a first first pixel circuit 21 to an N-th first pixel circuit 21 in a direction directed from the first region A1 to the second region A2 along the first direction X.

It can be understood that, in the direction directed from the second region A2 to the center of the first region A1 along the first direction X, the first first driving electrode 31 is closest to the second region A2, and the N-th first driving electrode 31 is farthest away from the second region A2.

In the direction directed from the first region A1 to the second region A2 along the first direction X, the first first pixel circuit 21 is closest to the first region A1, and the N-th first pixel circuit 21 is farthest away from the first region A1.

For example, an i-th first driving electrode 31 is electrically connected to an i-th first pixel circuit 21, where i is in a range of 1 to N, inclusive (i=1˜N). That is, the first first driving electrode 31 may be electrically connected to the first first pixel circuit 21 through a connection line 40, a second first driving electrode 31 may be electrically connected to a second first pixel circuit 21 through a connection line 40, . . . an (N−1)-th first driving electrode 31 may be electrically connected to an (N−1)-th first pixel circuit 21 through a connection line 40, and the N-th first driving electrode 31 may be electrically connected to the N-th first pixel circuit 21 through a connection line 40.

The above arrangement and connection manner are adopted in the embodiments of the present disclosure, which not only facilitates planning of the wiring path of the connection lines 40 and improves regularity of difference in lengths of any two adjacent connection lines 40, but may also reduce the number of connection lines 40 required for use, simplify the structure of the display panel 100, and reduce the difficulty in fabrication of the display panel 100.

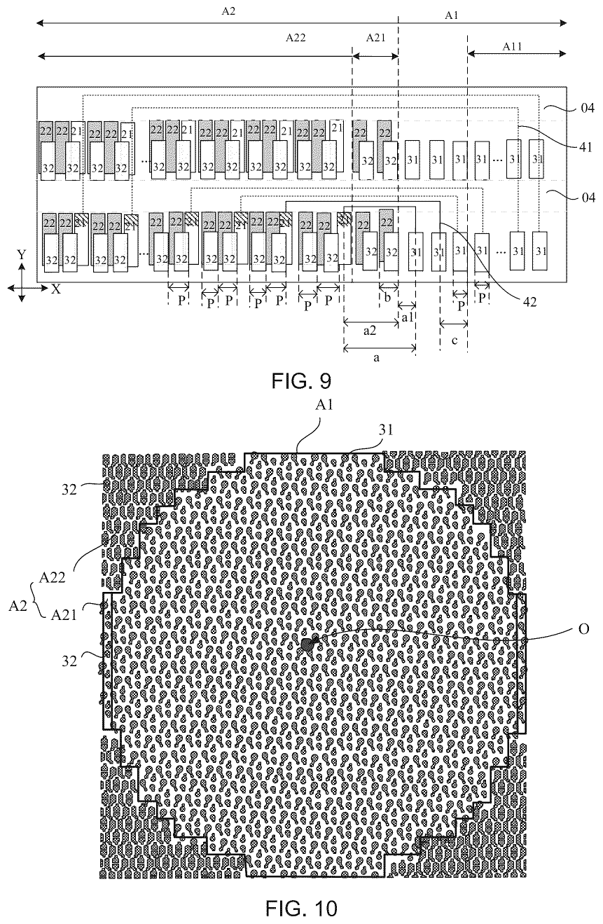

In some embodiments, referring to FIGS. 9 and 10. The second region A2 includes a first sub-region A21 and a second sub-region A22. The first sub-region A21 is adjacent to the first region A1.

In some examples, referring to FIG. 10, an area of the second driving electrode 32 located in the first sub-region A21 is less than an area of the second driving electrode 32 located in the second sub-region A22, and an area of the first driving electrode 31 is less than the area of the second driving electrode 32 located in the second sub-region A22.

Thus, transmittances of the first sub-region A21 and the first region A1 each are greater than a transmittance of the second sub-region A22.

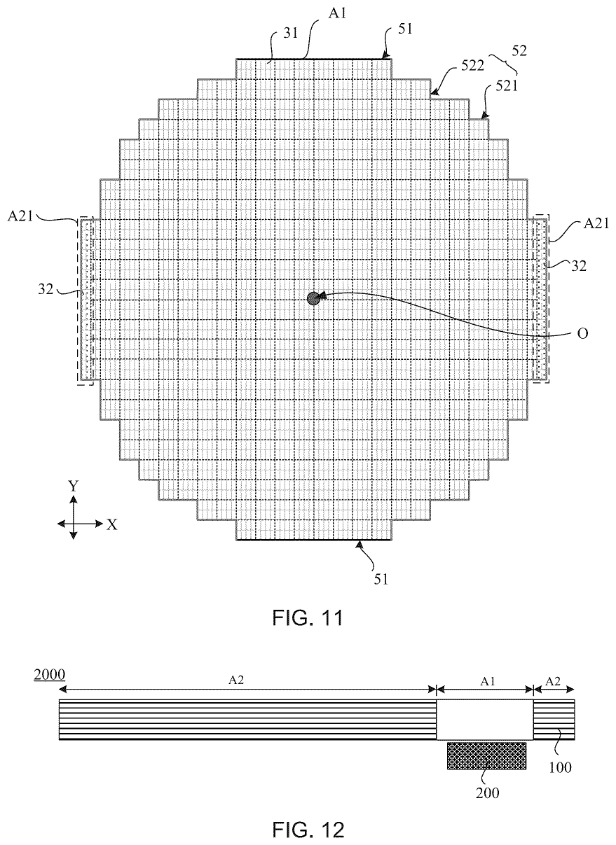

In some examples, referring to FIG. 11, the first driving electrodes 31 and the second driving electrodes 32 located in the first sub-region A21 are divided into a plurality of second basic units. A second basic unit includes 2k rows and 4h columns of driving electrodes. K and h are positive integers greater than or equal to 1.

For example, the second basic unit may include two rows and four columns of driving electrodes, four row and four columns of driving electrodes or two rows and eight columns of driving electrodes. Thus, the 2k rows and 4h columns of driving electrodes constitute the basic unit, which may be matched to the algorithm.

Thus, the first sub-region A21 and the first region A1 may adopt the same display algorithm to perform display, and the second sub-region A22 adopts a display algorithm different from the first sub-region A21 and the first region A1 to perform display. As a result, it ensures that the second sub-region A22, the first sub-region A21 and the first region A1 each are capable of rendering color accurately after being processed by respective display algorithms, avoids the color shifting problem caused by two regions adopting the same display algorithm for display, and weakens the sawtooth phenomenon happened to edges of the first sub-region A21 and the first region A1 when display is performed, thereby helping improve the display uniformity of the display panel 100, and improving the quality of the image displayed by the display panel 100.

In some embodiments, with continued reference to FIG. 9, the first region A1 and the second region A2 each include sub-pixel regions P. The dimension of the metal connection line 42 in the row direction is greater than a dimension of a sub-pixel region P in the row direction.

It will be noted that, the dimension of the metal connection line 42 in the row direction, for example, refers to a dimension of the metal connection line 42 in a direction where a row of first driving electrodes 31 extend (e.g., the first direction X shown in FIG. 9); the dimension of the sub-pixel region P in the row direction, for example, refers to a dimension of the sub-pixel region P in the direction where the row of first driving electrodes 31 extend (e.g., the first direction X shown in FIG. 9).

In some examples, with continued reference to FIG. 9, the first sub-region A21 includes two sub-pixel regions P in a row. In this case, in the row direction, a dimension a of a metal connection line 42 connected to a first driving electrode 31 that is located at an edge of the first region A1 and close to the second region A2 is greater than the dimension b of the sub-pixel region P.

In the embodiments, the first sub-region A21 includes at least one sub-pixel region P is arranged, so that the first sub-region A21 and the first region A1 as a whole may adopt the same display algorithm to perform display; and in this case, the second sub-region A22 adopts the display algorithm different from the first sub-region A21 and the first region A1 to perform display. As a result, it ensures that the second sub-region A22, the first sub-region A21 and the first region A1 each are capable of rendering color accurately after being processed by respective display algorithms, ameliorates the color shifting problem, and weakens the sawtooth phenomenon happened to the edges of the first sub-region A21 and the first region A1 when display is performed, thereby helping improve the display uniformity of the display panel 100, and improving the quality of the image displayed by the display panel 100.

In some embodiments, with continued reference to FIG. 9, the first region A1 includes an optical component region A11. A minimum distance c between the metal connection lines 42 and the optical component region A11 is greater than the dimension b of the sub-pixel region P in the row direction.

In some examples, a center of the optical component region A11 may coincide with the center of the first region A1.

In the embodiments, the minimum distance c between the metal connection lines 42 and the optical component region A11 is greater than the dimension b of the sub-pixel region P in the row direction, which may prevent the metal connection lines 42 from affecting the transmittance of the optical component region A11, and ensure that the ambient light may pass through the optical component region A11 and be incident onto optical component(s), so that the ambient light is collected by the optical component(s).

As a result, the optical component(s) can operate normally.

In some embodiments, with continued reference to FIG. 9, a length of a portion of the metal connection line 42 located in the first region A1 is less than a length of a portion of the metal connection line 42 located in the second region A2.

Referring to FIG. 9, considering an example of the first driving electrode 31 located at the edge of the first region A1 and close to the second region A2, a length a1 of a portion of a metal connection line 42 that is connected to the first driving electrode 31 and located in the first region A1 is less than a length a2 of a portion of the metal connection line 42 located in the second region A2.

In the embodiments, by making the length a1 of the portion of the metal connection line 42 located in the first region A1 less than the length a2 of the portion of the metal connection line 42 located in the second region A2, it may be possible to ensure that the transmittance of less region in the edge portion of the first region A1 is affected by the metal connection line 42 on the basis of the metal connection line 42 making up the arrangement space for the connection lines 40 electrically connected the row of first driving electrodes 31, and it may be possible to ensure that most regions in the first region A1 has a relatively high light transmittance.

In some embodiments, as shown in FIG. 11, a border of the first region A1 and the first sub-region A21 as a whole includes two straight segments 51 and two stepped segments 52, the stepped segment 52 includes first-type sub-segments 521 and second-type sub-segments 522.

The first-type sub-segment 521 is parallel to the first direction X, and the first-type sub-segment 521 crosses 4h columns of driving electrodes. The second-type sub-segment 522 is parallel to the second direction Y, and the second-type sub-segment 522 crosses 2k rows of driving electrodes.

Thus, driving electrodes at the edges of the first region A1 and the first sub-region A21 may adopt the same display algorithm to perform display, which avoids the color shifting problem caused by first driving electrodes 31 at the edge of the first region A1 and second driving electrodes 32 in the first sub-region A21 adopting different display algorithms for display, and eliminates the sawtooth phenomenon happened to the edges of the first sub-region A21 and the first region A1 when display is performed, thereby helping improve the display uniformity of the display panel 100, and improving the quality of the image displayed by the display panel 100.

In some embodiments, with continued reference to FIG. 10, a shape of a main body of at least one second driving electrode 32 located in the first sub-region A21 is the same as a shape of a main body of at least one first driving electrode 31. For example, the main body of the first driving electrode is in a shape of an ellipse or a circle, and the main body of the at least one second driving electrode 32 located in the first sub-region A21 is in the shape of the ellipse or the circle.

In the embodiments, the main body of the at least one second driving electrode 32 located in the first sub-region A21 and the main body of the at least one first driving electrode 31 have the same shape, and each are in the shape of the ellipse or the circle, which may make the border of the first region A1 and the first sub-region A21 be smoother and softer. When the display panel 100 displays images, the sawtooth phenomenon happened to the edges of the first sub-region A21 and the first region A1 may be weakened, which helps improve the display uniformity of the display panel 100, and improve the quality of the image displayed by the display panel 100.

In some embodiments, with continued reference to FIG. 10, an area of the at least one second driving electrode 32 located in the first sub-region A21 is equal to an area of the at least one first driving electrode 31.

In the embodiments, the area of the at least one second driving electrode 32 located in the first sub-region A21 and the area of the at least one first driving electrode 31 are equal, and are smaller than an area of the second driving electrode 32 in the second sub-region A22, which may not only simplify the fabrication process, but also reduce the diffraction happened to the first region A1, thereby improving the light transmittance of the first region A1.

Some embodiments of the present disclosure provide a display apparatus 2000.

As shown in FIG. 12, the display apparatus 2000 includes the display panel 100 described in the above embodiments, and optical component(s) 200 disposed on the non-light exit side of the display panel 100. An orthographic projection of the optical component 200 on the display panel 100 is located in the first region A1.

In some examples, the optical component 200 may include a photosensitive device. For example, the photosensitive device may include an image collector (e.g., a camera) or an infrared receiver.

For example, in the case where the photosensitive device includes the camera, a border of the camera may coincide with the border of the first region A1 or be located inside the border of the first region A1. A center of a lens of the camera may coincide with the center of the first region A1 and the first sub-region A21 as the whole (e.g., the center O of the first region A1 and the first sub-region A21 as the whole shown in FIGS. 9 and 10), thereby enhancing the imaging effect of the camera acquiring an image through the first region A1 to ensure a high quality image or photography of the camera.

The number of optical components 200 may be set according to the actual needs.

For example, the display apparatus 2000 may further include a frame, a source driver chip, a flexible printed circuit (FPC), a printed circuit board (PCB) or other electronic components.

Beneficial effects that may be achieved by the display apparatus 2000 provided in the embodiments of the present disclosure are the same as the beneficial effects that may be achieved by the display panel 100 provided in the above technical solutions, and are not repeated here.

The display apparatus 2000 may be any device that displays an image whether in motion (e.g., a video) or stationary (e.g., a still image), and whether textual or graphical. More specifically, it is anticipated that the described embodiments may be implemented in or associated with a variety of electronic devices, such as (but not limited to), a mobile phone, a wireless device, a personal digital assistant (PDA), a hand-held or portable computer, a global positioning system (GPS) receiver/navigator, a camera, an moving picture experts group 4 (MP4) video player, a video camera, a game console, a watch, a clock, a calculator, a television monitor, a computer monitor, an automobile display (e.g., an odometer display), a navigator, a cockpit controller and/or display, a display of camera views (e.g., a display of a rear-view camera in a vehicle), an electronic photo, an electronic billboard or sign, a projector, a building structure, a packaging and aesthetic structure (e.g., a display for displaying an image of a piece of jewelry), etc.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel having a first region and a second region, the second region surrounding at least part of the first region, the display panel comprising:
a plurality of first light-emitting devices located in the first region;
a plurality of second light-emitting devices, a plurality of first pixel circuits and a plurality of second pixel circuits that are located in the second region; and
a plurality of connection lines located in the first region and the second region, wherein at least one first pixel circuit in the plurality of first pixel circuits is electrically connected to at least one first light-emitting device in the plurality of first light-emitting devices through at least one connection line in the plurality of connection lines, and at least one second pixel circuit in the plurality of second pixel circuits is electrically connected to at least one second light-emitting device in the plurality of second light-emitting devices;
wherein at least one row of first light-emitting devices include a plurality of light-emitting repeat units that are arranged in a first direction, and a light-emitting repeat unit includes first light-emitting devices;
connection lines connected to at least two first light-emitting devices in the plurality of light-emitting repeat units are made of different materials.

2. The display panel according to claim 1, wherein
a direction directed from an alignment center of the plurality of light-emitting repeat units to an end of the plurality of light-emitting repeat units in the first direction is a first set direction; and
a light-emitting repeat unit adjacent to the second region in the first set direction in the plurality of light-emitting repeat units is referred to as a first repeat unit, and a connection line connected to at least one first light-emitting device in the first repeat unit is a metal connection line.

3. (canceled)

4. The display panel according to claim 2, wherein a direction directed from the alignment center of the plurality of light-emitting repeat units to another end of the plurality of light-emitting repeat units in the first direction is a second set direction; and
the first repeat unit includes a first first light-emitting device to a fourth first light-emitting device that are sequentially arranged in the second set direction;
wherein the connection line connected to a second first light-emitting device in the first repeat unit is the metal connection line.

5. The display panel according to claim 4, wherein
connection lines connected to the first first light-emitting device, a third first light-emitting device and the fourth first light-emitting device in the first repeat unit are transparent connection lines;
the transparent connection lines are arranged in a different layer from the metal connection line.

6. The display panel according to claim 4, wherein
connection lines connected to the first first light-emitting device and a third first light-emitting device in the first repeat unit extend to the second region through one of two wiring regions that are adjacent to the first repeat unit; and connection lines connected to the second first light-emitting device and the fourth first light-emitting device in the first repeat unit extend to the second region through another one of the two wiring regions that are adjacent to the first repeat unit; wherein any one of the wiring regions extends in the first direction; and/or
a dimension, in the first direction, of a connection line connected to the first first light-emitting device in the first repeat unit is less than a dimension, in the first direction, of a connection line connected to a third first light-emitting device in the first repeat unit;
a dimension, in the first direction, of the connection line connected to the second first light-emitting device in the first repeat unit is less than a dimension, in the first direction, of a connection line connected to the fourth first light-emitting device in the first repeat unit; and
the dimension, in the first direction, of the connection line connected to the fourth first light-emitting device is less than the dimension, in the first direction, of the connection line connected to the first first light-emitting device.

7. (canceled)

8. The display panel according to claim 1, wherein
a direction directed from an alignment center of the plurality of light-emitting repeat units to another end of the plurality of light-emitting repeat units in the first direction is a second set direction; and
a light-emitting repeat unit adjacent to the second region in the second set direction in the plurality of light-emitting repeat units is referred to as a second repeat unit, and a connection line connected to at least one first light-emitting device in the second repeat unit is a metal connection line.

9. (canceled)

10. The display panel according to claim 8, wherein
the second repeat unit includes a first first light-emitting device to a fourth first light-emitting device that are sequentially arranged in the second set direction;
wherein the connection line connected to the fourth first light-emitting device in the second repeat unit is the metal connection line.

11. The display panel according to claim 10, wherein
connection lines connected to the first first light-emitting device, a second first light-emitting device and a third first light-emitting device in the second repeat unit are transparent connection lines; and
the transparent connection lines are arranged in a different layer from the metal connection line.

12. The display panel according to claim 10, wherein
connection lines connected to the first first light-emitting device and a third first light-emitting device in the second repeat unit extend to the second region through one of two wiring regions that are adjacent to the second repeat unit; and connection lines connected to a second first light-emitting device and the fourth first light-emitting device in the second repeat unit extend to the second region through another one of the two wiring regions that are adjacent to the second repeat unit; wherein any one of the wiring regions extends in the first direction; and/or
a dimension, in the first direction, of a connection line connected to a third first light-emitting device in the second repeat unit is less than a dimension, in the first direction, of a connection line connected to the first first light-emitting device in the second repeat unit;
a dimension, in the first direction, of the connection line connected to the fourth first light-emitting device in the second repeat unit is less than a dimension, in the first direction, of a connection line connected to a second first light-emitting device in the second repeat unit; and
the dimension, in the first direction, of the connection line connected to the second first light-emitting device is less than the dimension, in the first direction, of the connection line connected to the third first light-emitting device.

13. (canceled)

14. The display panel according to claim 4, wherein
the first first light-emitting device corresponds to a red sub-pixel region, a second first light-emitting device corresponds to a green sub-pixel region, a third first light-emitting device corresponds to a blue sub-pixel region, and the fourth first light-emitting device corresponds to another green sub-pixel region.

15. The display panel according to claim 2, wherein a connection line connected to any one first light-emitting device, other than the first light-emitting device connected to the metal connection line, in the plurality of light-emitting repeat units arranged in the first direction is a transparent connection line;
the first region includes at least two sub-regions that are sequentially arranged in a set direction, and the set direction is directed from the alignment center of the plurality of light-emitting repeat units to any one end of the plurality of light-emitting repeat units in the first direction;
transparent connection lines connected to first light-emitting devices that are located in different sub-regions are located in different layers; and
the first light-emitting device connected to the metal connection line is located in a sub-region, farthest away from the alignment center of the plurality of light-emitting repeat units, in the at least two sub-regions.

16. (canceled)

17. The display panel according to claim 15, wherein
the at least two sub-regions include a first sub-region, a second sub-region, and a third sub-region that are sequentially arranged in the set direction:
for connection lines connected to W first light-emitting devices that are closest to the alignment center of the plurality of light-emitting repeat units in the plurality of light-emitting repeat units, a connection line includes a first wiring segment, a second wiring segment and a third wiring segment that are connected in sequence; the first wiring segment and the third wiring segment extend in the first direction and are located in different wiring regions, and the second wiring segment extends in a second direction; the second direction intersects the first direction; and the wiring regions extend in the first direction;
wherein W is a positive integer greater than or equal to 1 and less than or equal to 5; the second wiring segment is located in any one of the first sub-region, the second sub-region and the third sub-region.

18. The display panel according to claim 1, wherein
a direction directed from an alignment center of the plurality of light-emitting repeat units to an end of the plurality of light-emitting repeat units in the first direction is a first set direction, and a direction directed from the alignment center of the plurality of light-emitting repeat units to another end of the plurality of light-emitting repeat units in the first direction is a second set direction;
any one light-emitting repeat unit in the plurality of light-emitting repeat units includes a first first light-emitting device to a fourth first light-emitting device that are sequentially arranged in the second set direction;
connection lines connected to the first first light-emitting device and a third first light-emitting device in any one light-emitting repeat unit extend to the second region through one of two wiring regions that are adjacent to the light-emitting repeat unit; and
connection lines connected to a second first light-emitting device and the fourth first light-emitting device in any one light-emitting repeat unit extend to the second region through another one of the two wiring regions that are adjacent to the light-emitting repeat unit;
wherein any one wiring region extends in the first direction.

19. The display panel according to claim 18, wherein
in the first direction, a dimension of a connection line connected to any one of the first first light-emitting device and the third first light-emitting device is greater than a dimension of a connection line connected to any one of the second first light-emitting device and a fourth first light-emitting device.

20. The display panel according to claim 1, wherein
all the first light-emitting devices are divided into a plurality of first basic units, and a first basic unit includes 1k row and 2h columns of first light-emitting devices, wherein K and h are positive integers greater than or equal to 1.

21. The display panel according to claim 1, wherein
the first region includes at least two sub-regions and an edge region located between the at least two sub-regions and the second region in a set direction; the set direction is directed from the alignment center of the plurality of light-emitting repeat units to any one end of the plurality of light-emitting repeat units in the first direction;
at least part of the connection lines are metal connection lines;
at least connection lines connected to first light-emitting devices that correspond to green sub-pixel regions in the edge region are metal connection lines;
wherein the metal connection lines connected to the first light-emitting devices in the edge region and metal connection lines connected to first light-emitting devices in the first region are arranged in different layers.

22. The display panel according to claim 21, wherein the second region includes a first sub-region and a second sub-region, and the first sub-region is adjacent to the first region;
second light-emitting devices in the plurality of second light-emitting devices are arranged in the first sub-region;
all the first light-emitting devices and all the second light-emitting devices located in the first sub-region are divided into a plurality of second basic units, and a second basic unit includes 2k rows and 4h columns of light-emitting devices, wherein K and h are positive integers greater than or equal to 1.

23. The display panel according to claim 1, wherein
in first pixel circuits in the plurality of first pixel circuits and second pixel circuits in the plurality of second pixel circuits that are arranged in a same row in the first direction, the first pixel circuits are arranged between multiple second pixel circuits in the second pixel circuits at intervals.

24. (canceled)

25. A display apparatus, comprising:
the display panel according to claim 1; and
an optical component, wherein an orthographic projection of a photosensitive surface of the optical component on the display panel covers at least the first region.

26. The display panel according to claim 10, wherein
the first first light-emitting device corresponds to a red sub-pixel region, a second first light-emitting device corresponds to a green sub-pixel region, a third first light-emitting device corresponds to a blue sub-pixel region, and the fourth first light-emitting device corresponds to another green sub-pixel region.
